(19) United States
(12) Patent Application Publication
(10) Pub. No.: US 2010/0131215 A1
(43) Pub. Date: May 27, 2010

(54) INSULATION MONITORING SYSTEM & INSULATION DETECTING METHOD FOR ELECTRIC POWER SUPPLY SYSTEM

(76) Inventor: Bo-Kyeong Kim, Seoul (KR)

Correspondence Address: IPLA P.A., 3550 WILSHIRE BLVD., 17TH FLOOR, LOS ANGELES, CA, 90010, US

(21) Appl. No.: 12/377,110

(22) PCT Filed: Aug. 16, 2007
(86) PCT No.: PCT/KR2007/003913

§ 371 Date: Feb. 10, 2009

(30) Foreign Application Priority Data
Aug. 16, 2006 (KR) 10-2006-0077160
Aug. 16, 2007 (KR) PCT/KR2007/003913

(51) Int. Cl. G01R 31/02; G06F 19/00

(52) U.S. Cl. 702/58; 324/551

(57) ABSTRACT

An insulation detecting apparatus of the present invention comprises a voltage detecting means for detecting a voltage component of each of three phases, a zero-phase current transformer for detecting zero-phase leakage current flowing between the power line and ground, a leakage current detecting means for converting a leakage current component detected by the zero-phase current transformer into a voltage component and extracting a frequency component lower than a certain frequency or a frequency component of a commercial frequency band, a phase comparing means for detecting a phase difference between an output value of each of the three phases of the voltage detecting means and an output value of the leakage current detecting means, an analog-to-digital conversion unit for converting the output value of the leakage current detecting means into a digital component, an operation controller for reading and outputting a variety of data, and an input-output unit. According to the present invention, the insulation state of a power line can be detected by calculating active component leakage current between a power line including a load and the ground that is directly related to an insulation state or reactive component leakage current that is not directly related to the insulation state, but generated by ever-existing electrostatic capacitance, and the insulation detecting apparatus can be remotely controlled.

### TECHNICAL FIELD

The present invention relates to an insulation detecting apparatus and an insulation detecting method for a power line. More specifically, the present invention relates to an insulation detecting apparatus and method, in which an insulation state can be correctly detected by calculating insulation resistance and electrostatic capacitance of a power line including a load even when electrostatic capacitance between a three-phase power line including the load and the ground is in an unbalanced state, as well as in a balanced state.

According to the present invention, active component leakage current (or insulation resistance) between a power line including a load and the ground that is directly related to an insulation state or reactive component leakage current (or electrostatic capacitance) that is not directly related to the insulation state, but generated by ever-existing electrostatic capacitance, is calculated, displayed, and outputted together with an alarm. The insulation detecting apparatus can be remotely controlled through a communication unit.

### BACKGROUND ART

In a grounding system where the secondary side of a transformer is grounded, a conventional method of monitoring the insulation state of a power line including a load uses a method of detecting a zero-phase leakage current to component flowing through a ground line 5 or detecting zero-phase leakage current Io flowing between the power line 3 with a load and the ground as shown in FIG. 1. In the present invention, the power line means a power distribution line including a load, a high voltage distribution line, and a low voltage distribution line, and a zero-phase current transformer means a current transformer that can detect a zero-phase leakage current component. A voltage detection line means a component that can detect a voltage component by directly connecting to a wire or detect a voltage component of the power line using a non-contact method.

Hereinafter, the convention technique will be described in more detail.

As shown in FIG. 1, commercial alternating voltage is supplied to a load 4 through a transformer 1 for transforming voltage, a switch 2, and a power line 3.

In FIG. 1, the secondary side of the transformer 1 is a Y-connection, and the neutral point of the Y-connection is connected to the ground 6 through a ground line 5. Active component leakage current Ir and reactive component leakage current Ic flow between the power line 3 and the ground. The active component leakage current Ir is generated by an insulation resistance 9 component directly related to an insulation state, and the reactive component leakage current Ic is generated by an electrostatic capacitance 8 component that is not directly related to the insulation state, but generated if the power line 3 is long or a noise filter is installed at the input terminal of the load 4.

Zero-phase leakage current Io=Ir+Ic, which is a vector sum of the two components, flows through the ground line 5 of the transformer. Generally, mainly used is a method of detecting an insulation state only with the zero-phase leakage current Io, which is leakage current detected at the middle of the ground line 5 connected to the secondary side of the transformer 1 or at the secondary side of the zero-phase current transformer 10 that flows three phases of the power line 3 all together. Electrical devices using the method of detecting zero-phase leakage current to described above include an electric leakage breaker, electric leakage alarm, electric leakage detector, ground fault detector, and the like.

In a conventional method of detecting an insulation state only with zero-phase leakage current Io shown in FIG. 1, if unbalance of electrostatic capacitance 8 between the power line 3, or the load 4, and the ground is large among three phases, reactive leakage current Ic generated by the electrostatic capacitance 8 component that is not directly related to the insulation state is increased. Therefore, the zero-phase leakage current to is detected high even at a power line where insulation resistance 9 is small, i.e., where the insulation state is favorable, and thus the insulation state is displayed as unfavorable, or although constant active component leakage current Ir generated by the insulation resistance 9 component flows, since the active component leakage current Ir is small due to a magnetic field characteristic of the zero-phase current transformer 10, the detected zero-phase leakage current Io varies depending on the magnitude of the reactive component leakage current Ic generated by the electrostatic capacitance 8 component, and therefore, there is a problem in that the insulation state cannot be correctly detected.

Accordingly, required are an insulation detecting apparatus and an insulation detecting method that can correctly monitor an insulation state between the power line 3 including the load 4 and the ground even when electrostatic capacitance existing between the three-phase power line and the ground is in an unbalanced state, as well as in a balanced state.

### DISCLOSURE OF INVENTION

### Technical Problem

Accordingly, the present invention has been made in order to solve the above problems, and it is an object of the invention to provide an insulation detecting apparatus, in which an insulation state of a power line including a load can be correctly detected even when electrostatic capacitance between the three-phase power line including a load and the ground is in an unbalanced state, as well as in a balanced state.

Another object of the invention is to provide an insulation detecting apparatus, in which active component leakage current (or insulation resistance) between a power line and the ground that is directly related to an insulation state or reactive component leakage current (or electrostatic capacitance) that is not directly related to the insulation state, but generated by ever-existing electrostatic capacitance, can be calculated, displayed, and outputted together with an alarm, and which can be remotely controlled through a communication unit.

A further object of the invention is to provide an insulation detecting method, in which an insulation state of a power line including a load can be correctly detected even when electrostatic capacitance between the three-phase power line including a load and the ground is in an unbalanced state, as well as in a balanced state.

### Technical Solution

In order to accomplish the above objects of the invention, according to one aspect of the invention, there is provided an insulation detecting apparatus for detecting an insulation state, comprising: a voltage detecting means for transforming a voltage component of each of three phases of the power line including a load into a voltage component of a certain magnitude and collectively extracting voltage of each of the three phases; a zero-phase current transformer for detecting zero-phase leakage current flowing between the power line and ground; a leakage current detecting means for converting a leakage current component detected by the zero-phase current transformer into a voltage component and extracting a frequency component lower than a certain frequency or a frequency component of a commercial frequency band; a phase comparing means for detecting a phase difference between an output value of each of the three phases of the voltage detecting means and an output value of the leakage current detecting means; an analog-to-digital conversion unit for converting an analog component of the output value of the leakage current detecting means into a digital component; an operation controller for reading, outputting, operating, and controlling a variety of data; and an input-output unit for inputting and displaying a variety of data.

The leakage current detecting means comprises: the zero-phase current transformer for detecting leakage current between the power line and the ground; a current-to-voltage conversion unit for converting a leakage current component detected by the zero-phase current transformer into a voltage component; an amplification unit for amplifying the leakage current component converted by the current-to-voltage conversion unit; and a current filter unit for extracting a frequency component lower than a certain frequency or a frequency component of a commercial frequency band from the leakage current component amplified by the amplification unit 42.

The voltage detecting means comprises: a voltage detecting unit for transforming a voltage component of each of three phases of the power line including a load into a voltage component of a certain magnitude and collectively detecting three phase voltage; and a voltage filter unit for extracting a frequency component lower than a certain frequency or a frequency component of a commercial frequency band from the voltage component transformed by the voltage detecting unit.

The phase comparing means comprises: a voltage component waveform shaping unit for shaping a waveform of the voltage component outputted from the voltage detecting means; a current component waveform shaping unit for shaping a waveform of the leakage current component outputted from the leakage current detecting means; and a phase difference detecting unit for detecting a phase difference of an output of the current component waveform shaping unit from an output of the voltage component waveform shaping unit.

The voltage detecting unit is configured with any one of a resistor, a condenser, and a transformer having the same impedance between each phase of the three-phase power line and the ground.

The input-output unit comprises an input unit for inputting a variety of data, a display unit for displaying and outputting a variety of data, and a memory unit for storing a variety of data.

According to another aspect of the invention, there is provided an insulation detecting apparatus for detecting an insulation state, comprising: a voltage detecting means for transforming a voltage component of the power line including a load into a voltage component of a certain magnitude and sequentially extracting a voltage component of each of the three phases, one phase at a time; a zero-phase current transformer for detecting zero-phase leakage current flowing between the power line and ground; a leakage current detecting means for converting a leakage current component detected by the zero-phase current transformer into a voltage component and extracting a frequency component lower than a certain frequency or a frequency component of a commercial frequency band; a phase comparing means for detecting a phase difference between an output value of each of the three phases of the voltage detecting means and an output value of the leakage current detecting means; an analog-to-digital conversion unit for converting an analog component of the output value of the leakage current detecting means into a digital component; an operation controller for reading, outputting, operating, and controlling a variety of data; and an input-output unit for inputting and displaying a variety of data.

The voltage detecting means comprises: a voltage detecting unit for detecting a voltage component of each of three phases of the power line including a load and transforming the voltage component into a voltage component of a certain magnitude; a phase selection unit for selecting a voltage component of only one phase of three phases from the voltage component transformed by the voltage detecting unit; and a voltage filter unit for extracting a frequency component lower than a certain frequency or a frequency component of a commercial frequency band from the voltage component of the phase selected by the phase selection unit 32.

The leakage current detecting means comprises: the zero-phase current transformer for detecting leakage current between the power line and the ground; a current-to-voltage conversion unit for converting a leakage current component detected by the zero-phase current transformer 10 into a voltage component; a current filter unit for extracting a frequency component lower than a certain frequency or a frequency component of a commercial frequency band from the leakage current component converted by the current-to-voltage conversion unit; and an amplification unit for amplifying the leakage current component extracted by the current filter unit.

Preferably, the insulation detecting apparatus of the present invention further comprises a communication unit for remotely monitoring the insulation detecting apparatus from outside.

According to another aspect of the invention, there is provided insulation detecting method for a power line, which can detect an insulation state of the power line even when electrostatic capacitance between the power line and ground is in an unbalanced state, as well as in a balanced state, comprising the steps of: allowing the leakage current detecting means to detect a leakage current component Io1 from a zero-phase leakage current component detected at a secondary side of a zero-phase current transformer, allowing a voltage detecting means to detect a voltage component Vf by extracting only a frequency component, and detecting a phase difference of the leakage current component Io1 from the voltage component Vf of each of the three phases outputted from the voltage detecting means; calculating an in-phase component and a 90° phase-shifted component of the leakage current component Io1 of each phase; calculating a 90° phase-shifted zero value of each phase and/or an in-phase component zero value of each phase; verifying data on active component leakage current or reactive component leakage current of each phase calculated and stored in the memory unit in the step of calculating an in-phase component zero value of each phase and/or in the step of calculating a 90° phase-shifted component zero value of each phase; and externally displaying and/or outputting a combination of data recalculated in the step of verifying calculated data and the data used in the step of detecting Io1, Vf, and of each phase.

In a first insulation detecting method of the present invention, an active component leakage current generated by insulation resistors or reactive component leakage current generated by electrostatic capacitance is detected by calculating a reactive component zero leakage current, with which the reactive component leakage current generated by the electrostatic capacitance between the power line and the ground becomes zero in each of three phases.

In a second insulation detecting method of the present invention, an active component leakage current generated by insulation resistors or reactive component leakage current generated by electrostatic capacitance is detected by calculating an active component zero leakage current, with which the active component leakage current generated by the insulation resistors between the power line and the ground becomes zero in each of three phases.

In a third insulation detecting method of the present invention, an active component leakage current generated by insulation resistors or reactive component leakage current generated by electrostatic capacitance is detected by calculating an active component zero leakage current and a reactive component zero leakage current, with which the active component leakage current generated by the insulation resistors and the reactive component leakage current generated by the electrostatic capacitance between the power line and the ground become zero in each of three phases.

### ADVANTAGEOUS EFFECTS

According to the present invention, active leakage current generated by insulation resistors or insulation resistance, which is an insulation state of a power line including a load, can be correctly detected even when electrostatic capacitance between the three-phase power line including a load and the ground is in an unbalanced state, as well as in a balanced state, and in addition, information on the most unfavorable phase can be informed.

In addition, an alarm state is displayed on a display unit by comparing current leakage with an alarm level additionally inputted through an input unit or stored in a memory unit, or a variety of data or alarm states detected at a remote site can be remotely monitored through a remote control apparatus installed in the remote site and a communication unit having a communication and control function.

### BRIEF DESCRIPTION OF THE DRAWINGS

FIG. 1 shows a connection diagram describing a conventional method of monitoring leakage current.

FIG. 2 shows a connection diagram of an insulation detecting apparatus according to a first embodiment of the present invention.

FIG. 3 shows a connection diagram of an insulation detecting apparatus according to a second embodiment of the present invention.

FIG. 4 shows a connection diagram of an insulation detecting apparatus according to a third embodiment of the present invention.

FIG. 5 shows a connection diagram of an insulation detecting apparatus according to a fourth embodiment of the present invention.

FIG. 6 shows a connection diagram of an insulation detecting apparatus according to a fifth embodiment of the present invention.

FIG. 7 shows a connection diagram of an insulation detecting apparatus according to a sixth embodiment of the present invention.

FIG. 8 shows a block diagram of the insulation detecting apparatus used in FIGS. 2 to 7 according to a first embodiment of the insulation detecting apparatus.

FIG. 9 shows a detailed circuit diagram of the insulation detecting apparatus used in FIG. 8.

FIG. 10 shows a block diagram of the insulation detecting apparatus used in FIGS. 2 to 7 according to a second embodiment of the insulation detecting apparatus.

FIG. 11 shows a detailed circuit diagram of the insulation detecting apparatus used in FIG. 10.

FIG. 12 shows a detailed circuit diagram of the voltage detecting means used in FIGS. 8 and 9 according to a first embodiment of the voltage detecting means.

FIG. 13 shows a detailed circuit diagram of the voltage detecting means used in FIGS. 8 and 9 according to a second embodiment of the voltage detecting means.

FIG. 14 shows a detailed circuit diagram of the voltage detecting means used in FIGS. 10 and 11 according to a first embodiment of the voltage detecting means.

FIG. 15 shows a detailed circuit diagram of the voltage detecting means used in FIGS. 10 and 11 according to a second embodiment of the voltage detecting means.

FIG. 16 shows a detailed circuit diagram of the voltage detecting means used in FIGS. 10 and 11 according to a third embodiment of the voltage detecting means.

FIG. 17 shows a detailed circuit diagram of the voltage detecting means used in FIGS. 10 and 11 according to a fourth embodiment of the voltage detecting means.

FIG. 18 shows a detailed circuit diagram of the voltage detecting means used in FIGS. 10 and 11 according to a fifth embodiment of the voltage detecting means.

FIG. 19 shows a detailed circuit diagram of the voltage detecting means used in FIGS. 10 and 11 according to a sixth embodiment of the voltage detecting means.

FIG. 20 shows a detailed circuit diagram of the voltage detecting means used in FIGS. 10 and 11 according to a seventh embodiment of the voltage detecting means.

FIG. 21 shows a detailed circuit diagram of the voltage detecting means used in FIGS. 10 and 11 according to an eighth embodiment of the voltage detecting means.

FIG. 22 shows a detailed circuit diagram of the leakage current detecting means used in FIGS. 8 to 11 according to another embodiment of the leakage current detecting means.

FIG. 23 is a flowchart illustrating an insulation detecting method according to a first embodiment of the insulation detecting apparatus used in FIGS. 8 to 11.

FIG. 24 is a flowchart illustrating an insulation detecting method according to a second embodiment of the insulation detecting apparatus used in FIGS. 8 to 11.

FIG. 25 is a flowchart illustrating an insulation detecting method according to a third embodiment of the insulation detecting apparatus used in FIGS. 8 to 11.

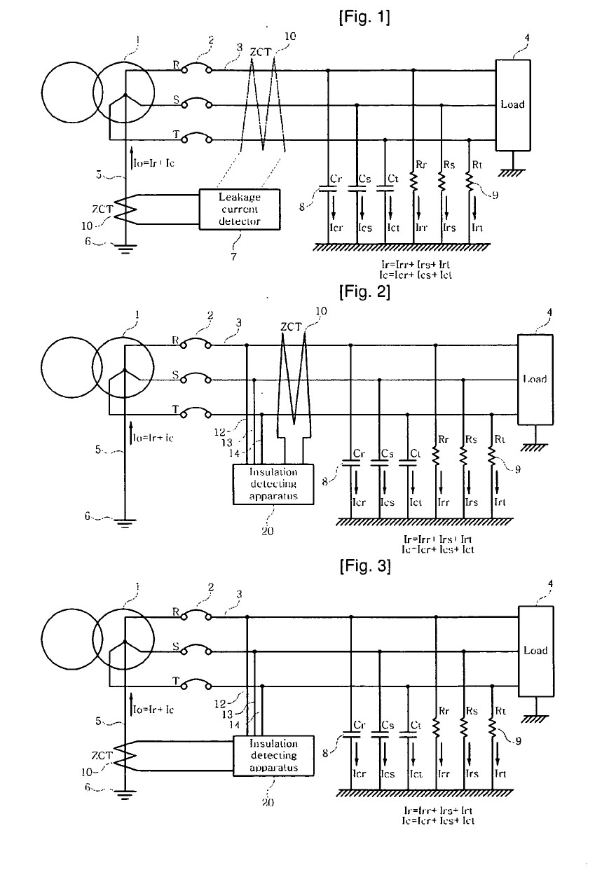

### MODE FOR THE INVENTION

Hereinafter, the preferred embodiments of the present invention will be described in detail with reference to the accompanying drawings.

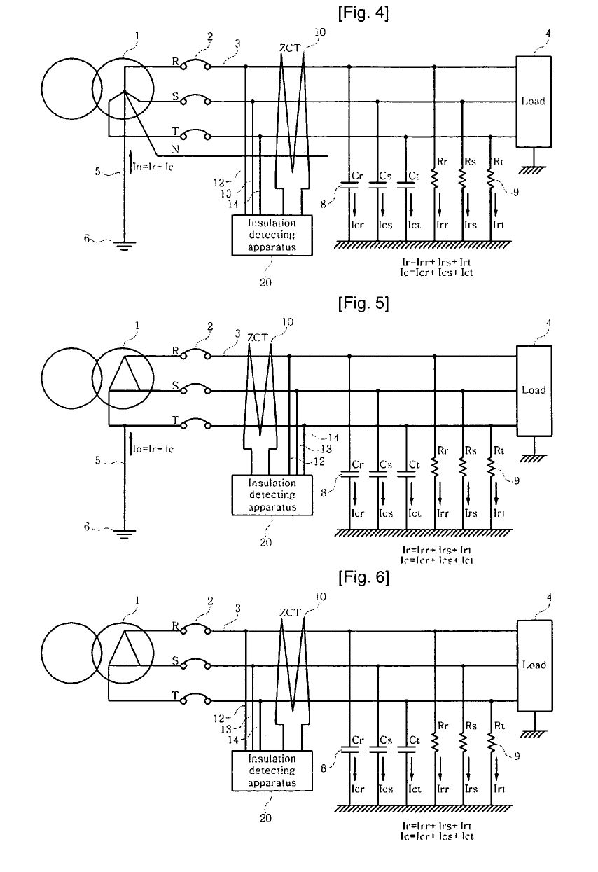

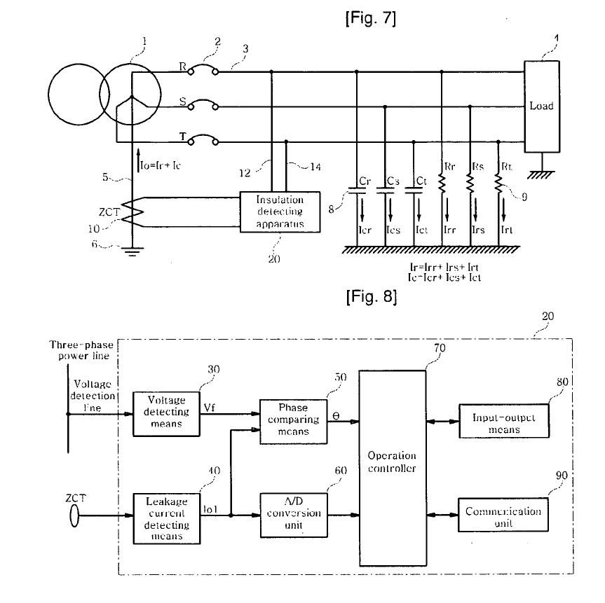

FIG. 2 shows a connection diagram of an insulation detecting apparatus according to a first embodiment of the present invention, FIG. 3 shows a connection diagram of an insulation detecting apparatus according to a second embodiment of the present invention, FIG. 4 shows a connection diagram of an insulation detecting apparatus according to a third embodiment of the present invention, FIG. 5 shows a connection diagram of an insulation detecting apparatus according to a fourth embodiment of the present invention, FIG. 6 shows a connection diagram of an insulation detecting apparatus according to a fifth embodiment of the present invention, and FIG. 7 shows a connection diagram of an insulation detecting apparatus according to a sixth embodiment of the present invention.

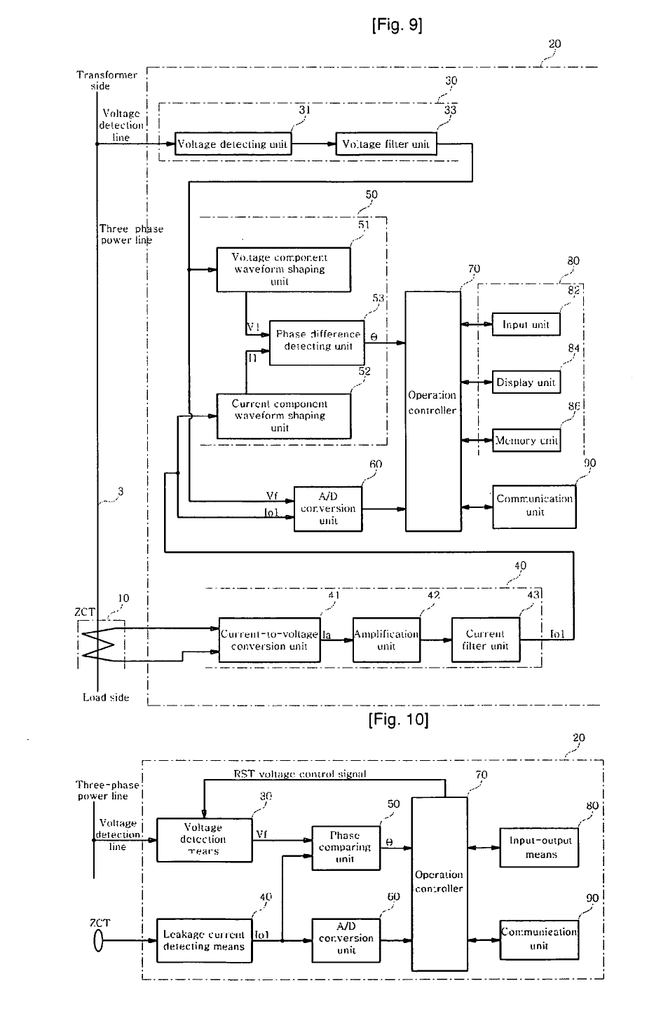

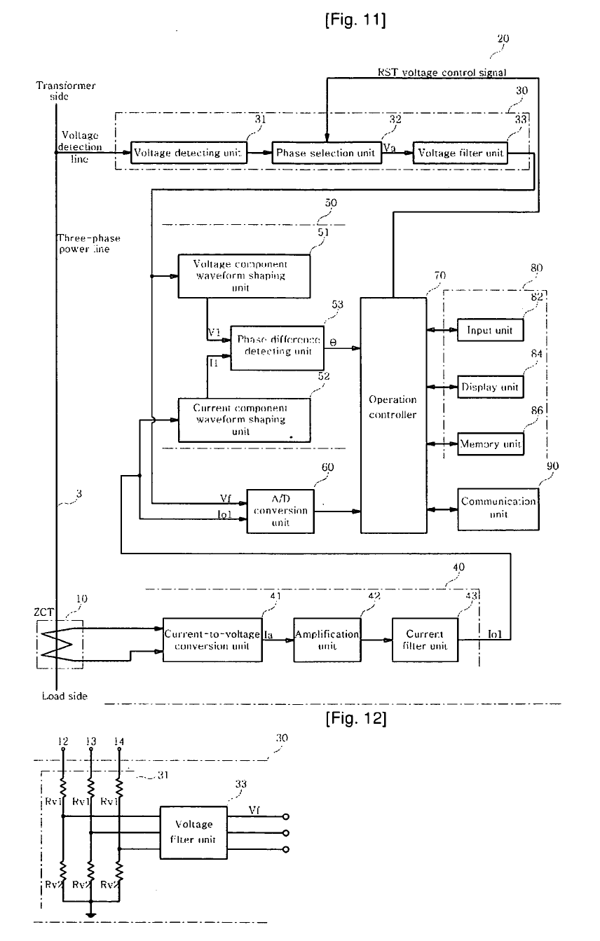

FIG. 8 shows a block diagram of the insulation detecting apparatus used in FIGS. 2 to 7 according to a first embodiment of the insulation detecting apparatus, FIG. 9 shows a detailed circuit diagram of the insulation detecting apparatus used in FIG. 8, FIG. 10 shows a block diagram of the insulation detecting apparatus used in FIGS. 2 to 7 according to a second embodiment of the insulation detecting apparatus, and FIG. 11 shows a detailed circuit diagram of the insulation detecting apparatus used in FIG. 10.

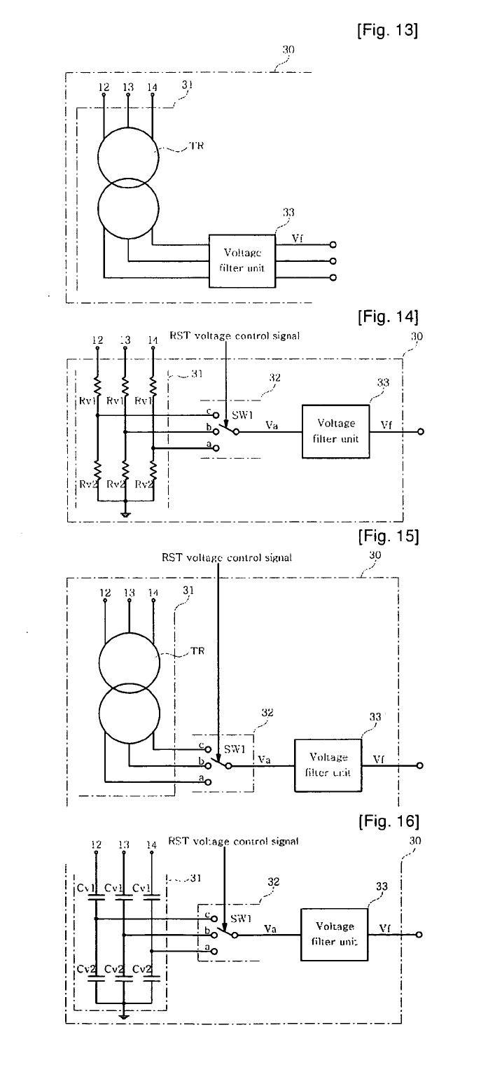

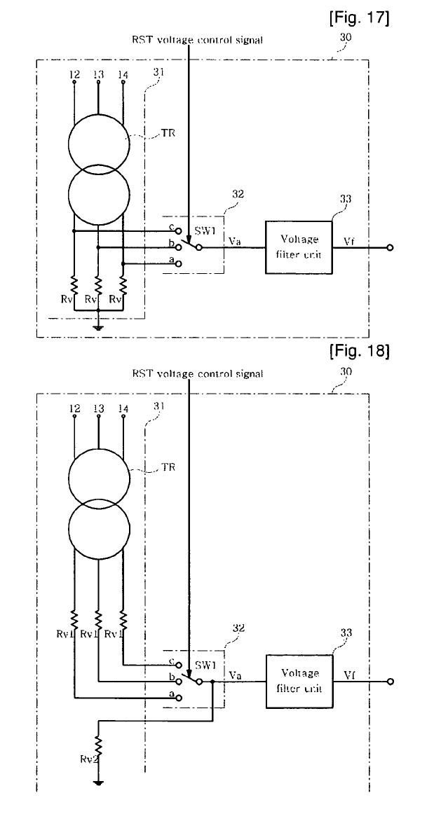

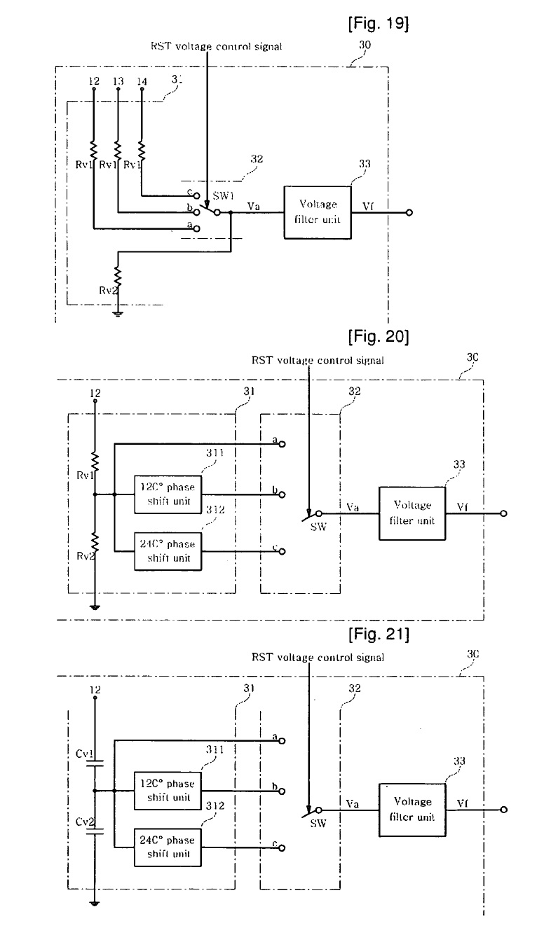

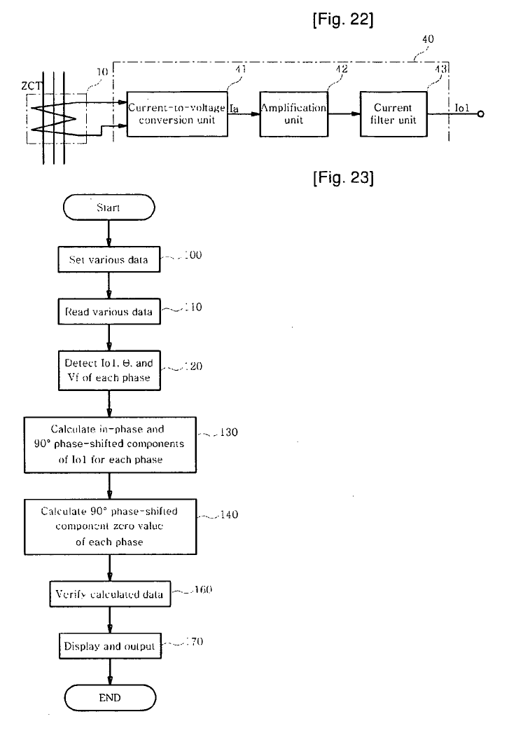

FIG. 12 shows a detailed circuit diagram of the voltage detecting means used in FIGS. 8 and 9 according to a first embodiment of the voltage detecting means, FIG. 13 shows a detailed circuit diagram of the voltage detecting means used in FIGS. 8 and 9 according to a second embodiment of the voltage detecting means, FIG. 14 shows a detailed circuit diagram of the voltage detecting means used in FIGS. 10 and 11 according to a first embodiment of the voltage detecting means, FIG. 15 shows a detailed circuit diagram of the voltage detecting means used in FIGS. 10 and 11 according to a second embodiment of the voltage detecting means, FIG. 16 shows a detailed circuit diagram of the voltage detecting means used in FIGS. 10 and 11 according to a third embodiment of the voltage detecting means, FIG. 17 shows a detailed circuit diagram of the voltage detecting means used in FIGS. 10 and 11 according to a fourth embodiment of the voltage detecting means, FIG. 18 shows a detailed circuit diagram of the voltage detecting means used in FIGS. 10 and 11 according to a fifth embodiment of the voltage detecting means, FIG. 19 shows a detailed circuit diagram of the voltage detecting means used in FIGS. 10 and 11 according to a sixth embodiment of the voltage detecting means, FIG. 20 shows a detailed circuit diagram of the voltage detecting means used in FIGS. 10 and 11 according to a seventh embodiment of the voltage detecting means, FIG. 21 shows a detailed circuit diagram of the voltage detecting means used in FIGS. 10 and 11 according to an eighth embodiment of the voltage detecting means, FIG. 22 shows a detailed circuit diagram of the leakage current detecting means used in FIGS. 8 to 11 according to another embodiment of the leakage current detecting means, and FIGS. 23 to 25 show flowcharts according to embodiments of the present invention used in FIGS. 8 to 11.

FIG. 2 shows an embodiment, in which the secondary side connection of the transformer 1 is a Y-connection, the neutral point is grounded, phase voltage to the ground is detected using voltage detection lines 12, 13, and 14 for detecting a voltage component of the power line 3, and a zero-phase current transformer 10 for detecting a zero-phase leakage current component of the power line 3 flowing to the ground is installed in the middle of the power line 3. FIG. 3 shows an embodiment almost similar to the embodiment shown in FIG. 2, in which the zero-phase current transformer 10 for detecting a zero-phase leakage current component of the power line 3 flowing to the ground is installed in the middle of the ground line 5 connected to the neutral point of the transformer 1.

FIG. 4 shows an embodiment almost similar to the embodiment shown in FIG. 2, which describes that the leakage detecting apparatus can be used in a three-phase four-wire system where the neutral phase (N-phase) of the transformer is laid together. FIG. 5 is an embodiment for describing that connection points of the voltage detection lines 12, 13, and 14 also can be implemented at a position further closer to the load than the zero-phase current transformer 10, in which although the secondary side connection of the transformer 1 is a delta connection, T-phase is grounded. FIG. 6 is an embodiment of a non-grounding method, in which the secondary side connection of the transformer 1 is a delta connection, and FIG. 7 is an embodiment almost similar to the embodiment shown in FIG. 2. Although FIG. 2 shows a method of detecting phase voltage, line voltage is detected using the voltage detection lines 12 and 14 in the embodiment of FIG. 7.

Although only six embodiments are described in the present invention as shown in FIGS. 2 to 7, like the embodiments of the voltage detecting means 30 that will be described below, there can be a variety of embodiments, such as an embodiment where the voltage component of one phase among three phases is detected and the other two voltage components are obtained by shifting the phase of the detected voltage component by 120 degrees, an embodiment where the voltage component of two phases among three phases is detected and the other one voltage component is obtained by shifting the phase of either of the detected voltage components by 120 degrees (or −120 degrees), an embodiment where line voltage is detected instead of phase voltage, and an embodiment of a resistance grounded neutral system where resistors are installed between the neutral point of the transformer 1 and the ground 6 to limit the magnitude of ground fault current.

FIGS. 8 to 11 show detailed circuit diagrams of the embodiments of the insulation detecting apparatus 20 shown in FIGS. 2 to 7. FIGS. 8 and 9 show an embodiment where a three phase voltage component between the three-phase power line 3 and the ground is inputted into a phase comparing means 50. FIGS. 10 and 11 show an embodiment where three phase voltage components between the three-phase power line 3 and the ground are sequentially inputted into the phase comparing means 50 one phase after another in response to an RST voltage control signal of the operation controller 70.

FIGS. 12 and 13 show detailed circuit diagrams of the embodiment of the voltage detecting means 30 shown in FIGS. 8 and 9. If the voltage component of each of three phases of the power line 3 is inputted through the voltage detection lines 12, 13, and 14, voltage of each phase is split by resistors Rv1 and Rv2 as shown in FIG. 12. FIG. 13 shows an embodiment, where the voltage component of the power line 3 is detected after the voltage is lowered to a certain level by a transformer TR, and a voltage filter unit 33 is configured to extract a frequency component lower than a certain frequency or a frequency component of a commercial frequency band from the detected voltage component. Although only two embodiments are shown above, there also can be an embodiment where condensers are used instead of the resistors as shown in FIG. 16 that will be described below or an embodiment where a line voltage component is detected instead of the phase voltage component of the power line 3 described above.

FIGS. 14 to 21 show detailed circuit diagrams of the embodiments of the voltage detecting means 30 shown in FIGS. 10 and 11, where a variety of embodiments for detecting a three phase or single-phase voltage component is shown. However, a variety of embodiments can be considered, such as an embodiment where a line voltage component is detected, an embodiment where a phase is shifted by −120 degrees instead of using a 240° phase shift unit 312, or the like. Describing FIGS. 14 to 21 further more, FIG. 14 shows an embodiment where if the voltage component of each of three phases of the power line 3 is inputted through the voltage detection lines 12, 13, and 14, voltage of each phase is split by resistors Rv1 and Rv2, and the voltage component of the power line 3 is detected by a phase selection unit 32 configured like a switch sw1 for selecting one phase at a time among three RST phases, in response to an RST voltage control signal outputted from the operation controller 70. In this embodiment, a voltage filter unit 33 is configured to extract a frequency component lower than a certain frequency or a frequency component of a commercial frequency band from the voltage component of one of three phases detected by the phase selection unit 32. FIG. 15 shows an embodiment where voltage is split by a transformer TR instead of the resistors used in the embodiment of FIG. 14. FIG. 16 shows an embodiment where voltage is split by condensers Cv1 and Cv2, not by the resistors used in the embodiment of FIG. 14. FIG. 17 shows an embodiment where resistors Rv installed between the secondary side of the transformer TR and the ground are added to the embodiment of FIG. 15, and there can be an embodiment where condensers are used instead of the resistors Rv in FIG. 17.

FIG. 18 shows an embodiment, where if the voltage component of each of three phases of the power line 3 is inputted through the voltage detection lines 12, 13, and 14, the voltage is lowered to a certain level by a transformer TR, and a voltage filter unit 33 is coupled to extract a frequency component lower than a certain frequency or a frequency component of a commercial frequency band from the voltage component that is split again by an upper resistor Rv1 and a resistor Rv2 connected to the ground. The upper resistor Rv1 is selected by the phase selection unit 32 for selecting one phase at a time among three RST phases in response to an RST voltage control signal outputted from the operation controller 70.

FIG. 19 shows an embodiment, where the transformer TR of the embodiment of FIG. 18 is not used, and the resistors Rv1 used in this embodiment preferably have resistance higher than those of the resistors Rv1 shown in FIGS. 12 to 18. FIGS. 20 and 21 show embodiments, where in order to detect the voltage component of the power line 3, only voltage component of one phase is detected, and voltage components of the other two phases are detected by shifting the phase of the voltage component detected by the voltage detecting unit 31 by 120 degrees and 240 degrees. In FIG. 20, in order to detect the voltage component of the power line 3, the voltage component of R-phase, for example, inputted through one voltage detection line 12 is split by two resistors Rv1 and Rv2 connected between the voltage detection line 12 and the ground. The split voltage component of R-phase is connected to a of the phase selection unit 32, and voltage components of the other S-phase and T-phase respectively use a 120° phase shift unit 311 for shifting the voltage component of R-phase by 120 degrees and a 240° phase shift unit 312 for shifting the voltage component of R-phase by 240 degrees. The voltage component having a phase difference of 120 degrees from the voltage component of R-phase, which is outputted from the 120° phase shift unit 311, is connected to b of the phase selection unit 32. The voltage component having a phase difference of 240 degrees from the voltage component of R-phase, which is outputted from the 240° phase shift unit 312, is connected to c of the phase selection unit 32. The voltage component of the power line 3 is detected by the phase selection unit 32 configured like a switch sw1 for selecting one phase at a time among three RST phases in response to an RST voltage control signal outputted from the operation controller 70, and a voltage filter unit 33 is configured to extract a frequency component lower than a certain frequency or a frequency component of a commercial frequency band from the voltage component of one of three phases detected by the phase selection unit 32. The resistors Rv1 and Rv2 preferably have high resistance.

FIG. 21 shows an embodiment that is different from the embodiment of FIG. 20 only in that condensers Cv1 and Cv2 are used instead of the resistors Rv1 and Rv2, where the condensers preferably have small capacitance. Although it is not shown in the figure of the embodiment, and the 120° phase shift unit 311 and the 240° phase shift unit 312 are used in FIGS. 20 and 21, there can be an embodiment where a −120° (minus)120° phase shift unit for shifting a phase by −120° is used instead of the 240° phase shift unit 312. Those skilled in the art will readily understood that there also can be an embodiment, where the voltage component of the power line 3 is detected by detecting two phase voltages or a line voltage using two voltage detection lines.

FIG. 22 shows a detailed circuit diagram according to another embodiment of the leakage current detecting means 40 of FIGS. 8 to 11, in which the leakage current detecting means 40 is configured in a sequence of a current-to-voltage conversion unit 41, an amplification unit 42, and a current filter unit 43 as shown in FIGS. 9 and 11. Contrarily, although FIG. 22 shows an embodiment where the leakage current detecting means 40 is configured in a different sequence of a current-to-voltage conversion unit 41, a current filter unit 43, and an amplification unit 42, there can be an embodiment where functions of the current-to-voltage conversion unit 41 and the amplification unit 42 are implemented as a single function. A variety of embodiments can be considered, such as an embodiment where the current-to-voltage conversion unit 41 is not implemented within the leakage current detecting means 40, but is embedded in the secondary winding of the zero-phase current transformer 10.

FIGS. 23 to 25 are flowcharts illustrating the operation of the insulation detecting apparatus 20 of the present invention shown in FIGS. 8 to 11 or illustrating the insulation detecting method of the present invention.

FIGS. 2, 8, 9, and 23 of the present invention will be described first. Referring to FIG. 2, the transformer 1 for transforming voltage provides power to the power line 3 through the switch 2. Reference symbol 5 denotes a ground line for connecting the neutral point of the transformer to the ground 6 for safety. On the other hand, while the power is provided to the load 4 through the switch 2 and the power line 3, active component leakage current Ir of each of three phases flows between the power line 3 including a load 4 and the ground through an insulation resistor 9 that is directly related to insulation aging.

The active component leakage current Ir is Ir=Irr+Irs+Irt that is a vector sum of Irr flowing through the insulation resistor Rr between R-phase and the ground, Irs flowing through the insulation resistor Rs between S-phase and the ground, and Irt flowing through the insulation resistor Rt between T-phase and the ground. In addition, between the power line 3 including the load 4 and the ground, reactive component leakage current Ic of each of three phases flows to the ground through electrostatic capacitance 8 that is not directly related to the insulation state, but generated if the power line 3 is long or an equipment such as a noise filter for reducing noises is installed at the input terminal of the load 4. The reactive component leakage current Ic is Ic=Icr+Ics+Ict that is a vector sum of Icr flowing through the electrostatic capacitor Cr between R-phase and the ground, Ics flowing through the electrostatic capacitor Cs between S-phase and the ground, and Ict flowing through the electrostatic capacitor Ct between T-phase and the ground. Accordingly, the zero-phase leakage current Io, which is leakage current flowing between the power line 3 and the ground, is represented as a vector sum of the active component leakage current Ir=Irr+Irs+Irt and the reactive component leakage current Ic=Icr+Ics+Ict.

If the zero-phase leakage current to component and the voltage component of each phase between the power line 3 and the ground are known, the active component leakage current Ir related to an insulation state of the power line 3 and the reactive component leakage current Ic that is not directly related to an insulation state, but flows between the power line 3 and the ground can be calculated.

The zero-phase current transformer (ZCT) 10 is used to detect the zero-phase leakage current Io component, and the voltage detection lines 12, 13, and 14 are used to detect the voltage component of each of three phases between the power line 3 and the ground. The voltage detection lines 12, 13, and 14 and the secondary side of the zero-phase current transformer 10 are connected to the insulation detecting apparatus 20 shown in FIG. 8.

### First Embodiment

FIG. 8 shows a block diagram of the insulation detecting apparatus used in FIGS. 2 to 7 according to a first embodiment of the insulation detecting apparatus.

The insulation detecting apparatus 20 of the present invention comprises a voltage detecting means 30 for detecting a voltage component between a power line 3 and the ground, transforming the detected voltage component into voltage of a certain magnitude, and extracting a frequency component lower than a certain frequency or a frequency component of a certain band; a leakage current detecting means 40 for converting zero-phase leakage current Io component, which is detected at the secondary side of the zero-phase current transformer 10 for detecting zero-phase leakage current Io between the power line 3 including the load 4 and the ground, into a voltage component, amplifying the converted voltage component, and extracting a frequency component lower than a certain frequency or a frequency component of a commercial frequency band; a phase comparing means 50 for comparing each of three phases of an output value of the voltage detecting means 30 with a phase of an output value of the leakage current detecting means 40; an analog-to-digital conversion unit 60 for converting an analog component of the output value of the leakage current detecting means 40 into a digital component; an operation controller 70 having an operation and control function for reading and outputting a variety of data; an input-output means 80 for inputting and displaying a variety of data; and a communication unit 90 for remotely controlling the insulation detecting apparatus from outside. The input-output means 80 includes an input unit 82, a display unit 84, and a memory unit 86.

Referring to FIG. 9, the voltage detecting means 30 for detecting a three phase voltage component of the power line 3 including a load comprises a voltage detecting unit 31 for transforming the three phase voltage component detected by the voltage detection lines 12, 13, and 14 into voltage of a certain magnitude, and a voltage filter unit 33 for extracting a frequency component lower than a certain frequency or a frequency component of a commercial frequency band from the three phase voltage component transformed by the voltage detecting unit 31. The leakage current detecting means 40 comprises a current-to-voltage conversion unit 41 for converting leakage current component, which is detected at the secondary side of the zero-phase current transformer 10 for detecting the zero-phase leakage current Io between the power line 3 including the load 4 and the ground, into a voltage component, an amplification unit 42 for amplifying the leakage current component Ia converted by the current-to-voltage conversion unit 41, and a current filter unit 43 for extracting a frequency component lower than a certain frequency or a frequency component of a commercial frequency band from a leakage current component corresponding to the zero-phase leakage current Io component amplified by the amplification unit 42. The phase comparing means 50 includes a voltage component waveform shaping unit 51 for shaping the waveform of the voltage component of each of three phases outputted from the voltage detecting means 30, a current component waveform shaping unit 52 for shaping the waveform of the leakage current component Io1 corresponding to the zero-phase leakage current Io component outputted from the leakage current detecting means 40, and a phase difference detecting unit 53 for detecting a phase difference between an output of the voltage component waveform shaping unit 51 and an output of the current component waveform shaping unit 52. Only one output value of the leakage current detecting means 40 is inputted into the analog-to-digital conversion unit 60 in FIG. 8. However, two analog components, i.e., the output value of the leakage current detecting means 40 and the output value of the voltage detecting means 30 for additionally detecting the magnitude of the voltage component, are inputted into the analog-to-digital conversion unit 60 in FIG. 9.

Accordingly, if the number of components inputted into the analog-to-digital conversion unit 60 is two as described above, a voltage component value of the power line 3 is read to calculate both leakage current and insulation resistance, and if one component is inputted, only the leakage current is calculated and the insulation resistance is not calculated, choice of which will vary depending on embodiments. In the present invention, an embodiment where even the insulation resistance is calculated will be described to express a variety values needed for monitoring an insulation state.

Hereinafter, the present invention is described in more detail referring to FIG. 9 showing a first embodiment of the insulation detecting apparatus 20 and FIG. 23 showing a flowchart of the insulation detecting apparatus 20.

A first insulation detecting method of the present invention shown in FIG. 23, capable of detecting an insulation state of a power line even when electrostatic capacitance between the power line and the ground is in an unbalanced state, as well as in a balanced state, comprises the steps of: allowing the leakage current detecting means 40 to detect a leakage current component Io1 from a zero-phase current component detected at the secondary side of the zero-phase current transformer, allowing the voltage detecting means to detect a voltage component Vf of each of three phases by extracting only a frequency component, and detecting a phase difference of the leakage current component Io1 from the voltage component Vf of each of three phases outputted from the voltage detecting means 30; calculating an in-phase component and a 90° phase-shifted component of the leakage current component Io1 of each phase; calculating a 90° phase-shifted component zero value of each phase; verifying data on active component leakage current or reactive component leakage current of each phase calculated and stored in the memory unit in the step of calculating a 90° phase-shifted component zero value of each phase; and externally displaying and/or outputting a combination of data recalculated in the step of verifying calculated data and the data used in the step of detecting Io1, Vf, and of each phase.

As shown in FIGS. 9 and 23, on the main flow stored in the memory unit 86 of the insulation detecting apparatus 20, the input unit 82 sets a variety of data used in the insulation detecting apparatus 20 using a constitutional component such as a keypad or a switch 100, in which the input unit has a function for setting a variety of data, e.g., a number address, an alarm setting value, and the like of each insulation detecting apparatus 20 if a plurality of insulation detecting apparatuses 20 is installed. Next, a read operation is performed on a variety of data set by the input unit 82, previously stored in the memory unit 86, or inputted from a remote external site through the communication unit 90 110.

If the step of detecting Io1, Vf, and of each phase 120 is performed, the zero-phase leakage current component Io detected at the secondary side of the zero-phase current transformer 10 shown in FIGS. 8 and 9 is converted into a voltage component by the current-to-voltage conversion unit 41 that converts current to voltage and amplified by the amplification unit 42. Then, a current component Io1 corresponding to the zero-phase leakage current, from which a frequency component lower than a certain frequency or a frequency component of a commercial frequency band is extracted by the current filter unit 43, is outputted to the analog-to-digital conversion unit 60 and the phase comparing means 50. The component Io1 value corresponding to the zero-phase leakage current inputted into the analog-to-digital conversion unit 32 (60) is converted into a digital value, and the operation controller 70 reads and stores the digital value into the memory unit 86.

Then, as described above, the voltage detecting unit 31 of FIG. 16 used in the embodiments shown in FIGS. 12 to 16 or another embodiment splits the voltage component of each of three phases between the power line 3 and the ground inputted through the voltage detection lines 12, 13, and 14 into voltages that can be used in the insulation detecting apparatus 20, using resistors, condensers, or a transformer. The voltage component Vf of each of three phases (Vf_r of R-phase, Vf_s of S-phase, or Vf_t of T-phase), i.e., a split voltage from which a frequency component lower than a certain frequency or a frequency component of a commercial frequency band is extracted by the voltage filter unit 33, is outputted to the phase comparing means 50 and the analog-to-digital conversion unit 60. The voltage component Vf of each of three phases to the ground inputted into the analog-to-digital conversion unit 60 is converted into a digital value, and the operation controller 70 reads and stores the digital value into the memory unit 86.

Using the values of three voltage components Vf_r, Vf_s, and Vf_t to the ground of three phases inputted into the phase comparing means 50, whose waveforms are shaped by the voltage component waveform shaping unit 51, and the value of one leakage current component Io1 corresponding to the zero-phase leakage current component outputted from the leakage current detecting means 40, whose waveform is shaped by the current component waveform shaping unit 52, the phase difference detecting unit 53 detects three phase differences between the three voltage components of three phases outputted from the voltage component waveform shaping unit 51 and the one leakage current component outputted from the current component waveform shaping unit 52, i.e., a phase difference r of the leakage current component Io1 for the voltage component of R-phase Vf_r, a phase difference s of the leakage current component Io1 for the voltage component of S-phase Vf_s, and a phase difference t of the leakage current component Io1 for the voltage component of R-phase Vf_t, and the operation controller 70 reads and stores the three phase differences into the memory unit 86.

An example of calculating the aforementioned Vf, Io1, and is described. For the convenience of explanation, it is assumed that an amplification-related coefficient of the leakage current detecting means 40 including the zero-phase current transformer 10 is one, and an amplification-related coefficient of the voltage detecting means 30 is 0.001 (i.e. 1/1000).

The voltage between the three-phase power line 3 and the ground is 220V, and the frequency is 60 Hz. The leakage currents flowing through the insulation resistors between the three-phase power line and the ground are respectively Irr=1 mA for R-phase, Irs=40 mA for S-phase, and Irt=1 mA for T-phase. The leakage currents flowing through the electrostatic capacitors between the three-phase power line and the ground are respectively Icr=60 mA for R-phase, Ics=20 mA for S-phase, and Ict=20 mA for T-phase.

The values detected and stored in the memory unit 86 in the step of detecting the voltage component Vf, leakage current component Io1, and phase difference 120 are such that Io1 is 76.3 mA, Vf_r, Vf_s, and Vf_t are 220 mV respectively, r is 104.8, s is −15.2, and t is −135.2.

Next, if the step of calculating an in-phase and a 90° phase-shifted components of the leakage current component Io1 of each phase 130 is performed, the leakage current component Io1 and the phase differences r, s, and t detected and stored in the memory unit 86 in the step of detecting the voltage component Vf, leakage current component Io1, and phase difference 120 are read. For each of three phases, an in-phase component cos value and a 90° phase-shifted component sin value for the voltage of the leakage current Io1 corresponding to the zero-phase leakage current are calculated and stored in the memory unit 86. Describing it more specifically, the in-phase component leakage current of R-phase Io1rr is Io1×cos r, the 90° phase-shifted component leakage current of R-phase Io1cr is Io1×sin r, the in-phase component leakage current of S-phase Io1rs is Io1×cos s, the 90° phase-shifted component leakage current of S-phase Io1cs is Io1×sin s, the in-phase component leakage current of T-phase Io1rt is Io1×cos t, and the 90° phase-shifted component leakage current of T-phase Io1ct is Io1×sin t.

Substituting the values described in the above example and approximately calculating zero-phase leakage currents, Io1rr=−19.5 mA, Io1cr=73.8 mA, Io1rs=73.6 mA, Io1cs=−20.0 mA, Io1rt=−54.1 mA, and Io1ct=−53.8 mA, and therefore, the zero-phase leakage current Io for the R-phase voltage is −19.5+j73.8 mA, the zero-phase leakage current to for the S-phase voltage is 73.6−j20 mA, and the zero-phase leakage current to for the T-phase voltage is −54.1−j53.8 mA.

Next, before describing the step of calculating a 90° phase-shifted component zero value of each phase 140, for the values described above, a functional relation between an in-phase component leakage current value and a 90° phase-shifted component leakage current value for voltage of each of three phases will be described first. The zero-phase leakage current Io component flowing between the power line 3 including the load 4 and the ground can be expressed as shown in Equation 1. Next, the zero-phase leakage current for a three phase voltage component shown in Equation 1 is converted into a voltage component value of R-phase, and a value corresponding to the zero-phase leakage current component of a voltage component that is in-phase with the R-phase voltage, i.e., Io1rr, is expressed as shown in Equation 2, and a value corresponding to the zero-phase leakage current component of the voltage component that is 90° phase-shifted from the R-phase voltage, i.e., Io1cr, is expressed as shown in Equation 3.

$$\begin{matrix}\begin{matrix}{Io}^{°} = \frac{{V}_{{R}^{°}}}{Rr} + \frac{{V}_{{S}^{°}}}{Rs} + \frac{{V}_{{T}^{°}}}{Rt} + \\ j ( ω Cr {V}_{{R}^{°}} + ω Cs {V}_{{S}^{°}} + ω Ct {V}_{{T}^{°}} ) \\ = {Irr}^{°} + {Ics}^{°} + {Ict}^{°} + j ( {Icr}^{°} + {Ics}^{°} + {Ict}^{°} )\end{matrix} \\ Here , V and I are vector functions . & < Equation 1 > \\ Irr - \frac{Irs}{2} - \frac{Irt}{2} - \frac{\sqrt{3}}{2} Ics + \frac{\sqrt{3}}{2} Ict \\ Here , I is a real value . & < Equation 2 > \\ Icr - \frac{Ics}{2} - \frac{Ict}{2} + \frac{\sqrt{3}}{2} Irs - \frac{\sqrt{3}}{2} Irt \\ Here , I is a real value . & < Equation 3 >\end{matrix}$$

The relational expression between the in-phase component leakage current and the 90° phase-shifted component leakage currents of S-phase and T-phase is that they respectively have 120° and −120° phase differences from the in-phase component leakage current and the 90° phase-shifted component leakage current of R-phase.

As shown in Equations 2 and 3, it is understood that the in-phase component leakage current of R-phase includes not only active component leakage current Irr flowing due to the insulation resistance of R-phase, but also active component leakage currents Irs and Irt flowing due to the insulation resistances of S-phase and T-phase and reactive component leakage currents Ics and Ict flowing due to the electrostatic capacitances of S-phase and T-phase. The 90° phase-shifted component leakage current of R-phase includes not only reactive component leakage current Irr flowing due to the electrostatic capacitance of R-phase, but also reactive component leakage currents Ics and Ict flowing due to the electrostatic capacitances of S-phase and T-phase and active component leakage currents Irs and Irt flowing due to the insulation resistances of S-phase and T-phase. Then, it can be conjectured from Equations 2 and 3 that an insulation state cannot be correctly obtained by a conventional method of detecting zero-phase leakage current Io generated by a zero-phase current transformer.

Three methods of calculating an in-phase component zero value of each phase will be described.

That is, a first method is for calculating a reactive component zero leakage current value with which the reactive component leakage current Ic becomes zero, a second method is for calculating an active component zero leakage current value with which the active component leakage current Ir becomes zero, and a third method is for calculating an active component zero leakage current value and a reactive component zero leakage current value with which the reactive component leakage current Ic and the active component leakage current Ir become zero.

1) A Case of Calculating a Reactive Component Zero Leakage Current Value with which the Reactive Component Leakage Current Ic Becomes Zero

First, the step of calculating a 90° phase-shifted component zero value of each phase 140 is described (refer to FIG. 23).

A reactive component leakage current value generated by electrostatic capacitance with which a reactive component leakage current becomes zero is calculated for each of three phases. This value is calculated to understand that active component leakage current of which component flows at the secondary side of the zero-phase current converter 10 if the reactive component leakage current Ic generated by the electrostatic capacitance becomes zero. Describing it easily, it is to make reactive component leakage currents generated by electrostatic capacitances be balanced in all three phases. However, a predetermined value that is slightly larger than the zero value can be selected. A reactive component leakage current value of R-phase is calculated first to find out the phase and magnitude of reactive component zero leakage current Ic′ that should be additionally flown through the primary winding of the zero-phase current transformer 10 to make Io1cr zero, i.e., the value of Equation 3 becomes zero. Io1rr and Io1cr of R-phase, Io1rs and Io1cs of S-phase, and Io1rt and Io1ct of T-phase described in the above example and stored in the memory unit 86 are read. Then, Icr′, Ics′, and Ict′ values are calculated so that the 90° phase-shifted reactive component leakage current of R-phase becomes zero, i.e., the value of Equation 3 becomes zero. If the Icr′, Ics′, and Ict′ values are put into Equation 2 and an in-phase component leakage current value Io1rr′ of R-phase is calculated, Io1rr′ becomes as shown in Equation 4. If the Icr′, Ics′, and Ict′ values are put into Equation 3 and a 90° phase-shifted component leakage current value Io1cr′ of R-phase is calculated, Io1rr′ becomes as shown in Equation 5.

$$\begin{matrix}If {Icr}^{′} is applied , & \\ Irr - \frac{Irs}{2} - \frac{Irt}{2} - \frac{\sqrt{3}}{2} Ics + \frac{\sqrt{3}}{2} Ict = - 19.5 \\ If {lcs}^{′} is applied , \\ Irr - \frac{Irs}{2} - \frac{Irt}{2} - \frac{\sqrt{3}}{2} ( Ics + {Ics}^{′} ) + \frac{\sqrt{3}}{2} Ict = - 19.5 - \frac{\sqrt{3}}{2} {Ics}^{′} \\ If {lct}^{′} is applied , \\ Irr - \frac{Irs}{2} - \frac{Irt}{2} - \frac{\sqrt{3}}{2} Ics + \frac{\sqrt{3}}{2} ( Ict + {Ict}^{′} ) = - 19.5 + \frac{\sqrt{3}}{2} {Ict}^{′} & < Equation 4 > \\ If {lcr}^{′} is applied , & \\ ( Icr + {Icr}^{′} ) - \frac{Ics}{2} - \frac{Ict}{2} + \frac{\sqrt{3}}{2} Irs - \frac{\sqrt{3}}{2} Irt = 73.8 + {Icr}^{′} \\ If {lcs}^{′} is applied , \\ Icr - \frac{( Ics + {Ics}^{′} )}{2} - \frac{Ict}{2} + \frac{\sqrt{3}}{2} Irs - \frac{\sqrt{3}}{2} Irt = 73.8 - \frac{{Ics}^{′}}{2} \\ If {lct}^{′} is applied , \\ Icr - \frac{Ics}{2} - \frac{( Ict + {Ict}^{′} )}{2} + \frac{\sqrt{3}}{2} Irs - \frac{\sqrt{3}}{2} Irt = 73.8 - \frac{{Ict}^{′}}{2} & < Equation 5 >\end{matrix}$$

Since the value of Equation 5 becomes zero when Icr′=−73.8, Ics′=147.6, and Ict′=147.6, if the values are put into Equation 4 respectively, the zero-phase leakage currents become −19.5+j0, −147.3+j0, and 108.3+j0, and the Icr′, Ics′, and Ict′ values of R-phase are stored in the memory unit 86.

Next, if zero-phase leakage currents of S-phase and R-phase are respectively calculated in the same manner as that of R-phase, following results will be obtained.

The reactive component leakage current value of S-phase becomes zero when Icr′=−40.0, Ics′=20.0, and Ic=−40.0, and if the values are put as described above, the zero-phase leakage currents become 39.9+j0, 73.6+j0, and 108.3+j0, and the Icr′, Ics′, and Ict′ values of S-phase are stored in the memory unit 86.

The reactive component leakage current value of T-phase becomes zero when Icr′=−107.5, Ics′=−107.5, and Ict′=53.8, and if the values are put as described above, the zero-phase leakage currents become 39.0+j0, −147.3+j0, and −54.1+j0, and the Icr′, Ics′, and Ict′ values of T-phase are stored in the memory unit 86.

Next, the step of verifying the calculated data 160 is described.

Reactive component zero leakage current Ic′ values calculated and stored in the memory unit 86 in the step of calculating a 90° phase-shifted component zero value of each phase 140, with which the reactive component leakage current of each phase becomes zero, are read. Then, using the zero-phase leakage current for R-phase voltage Io=19.5+j73.8 mA, the zero-phase leakage current for S-phase voltage Io=73.6−j20.0 mA, and the zero-phase leakage current for T-phase voltage Io=−54.1−j53.8 mA, which are calculated in the step of calculating an in-phase and a phase-shifted components of the leakage current component Io1 of each phase 130, it is examined that an in-phase component and a 90° phase-shifted component of which phase is large or small. Examining a large value first, since the largest in-phase component is +73.6 of S-phase, if the in-phase component of S-phase is added + (plus), the active component leakage current of S-phase Irs or the reactive component leakage current of R-phase Icr is larger than the active component leakage current of T-phase Irt, the active component leakage current of R-phase Irr, or the reactive component leakage current of T-phase Ict. Since the largest 90° phase-shifted component is +73.8 of R-phase, if the 90° phase-shifted component of R-phase is added + (plus), the reactive component leakage current of R-phase Icr or the active component leakage current of S-phase Irs is larger than the reactive component leakage current of S-phase Ics, the reactive component leakage current of T-phase Ict, or the active component leakage current of T-phase lit. Therefore, this case satisfies two conditions, and thus, although a small value is examined, among the zero-phase leakage current components flowing between the power line 3 and the ground, active component leakage current generated by insulation resistors is largest in S-phase, and reactive component leakage current generated by electrostatic capacitance is largest in R-phase. Accordingly, in the cases where reactive component leakage current becomes zero, a condition corresponding to R-phase where in-phase component leakage current of S-phase is plus + is Icr′=40 with which the reactive component leakage current of S-phase becomes zero. At this point, the in-phase active component leakage current of S-phase is +39. Accordingly, it is understood that actual reactive component leakage current of R-phase flowing between the power line 3 and the ground due to the electrostatic capacitance is larger than those of the other phases by +40 mA, and actual active component leakage current of S-phase flowing between the power line 3 and the ground due to the insulation resistors is larger than those of the other phases by +39 mA.

2) A Case of Calculating an Active Component Zero Leakage Current Value with which the Active Component Leakage Current Ir Becomes Zero

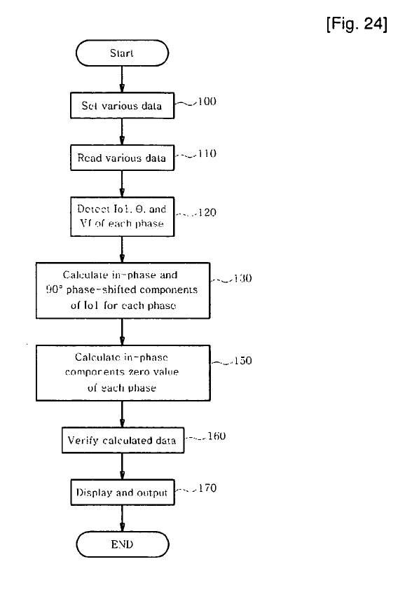

A second insulation detecting method of the present invention shown in FIG. 24, capable of detecting an insulation state of a power line even when electrostatic capacitance of the power line to the ground is in an unbalanced state, as well as in a balanced state, comprises the steps of: allowing the leakage current detecting means 40 to detect a leakage current component Io1 from a zero-phase current component detected at the secondary side of the zero-phase current transformer, allowing the voltage detecting means to detect a voltage component Vf of each of three phases by extracting only a frequency component, and detecting a phase difference of the leakage current component Io1 from the voltage component Vf of each of three phases outputted from the voltage detecting means 30; calculating an in-phase component and a 90° phase-shifted component of the leakage current component Io1 of each phase; calculating an in-phase component zero value of each phase; verifying data on active component leakage current or reactive component leakage current of each phase calculated and stored in the memory unit in the step of calculating an in-phase component zero value of each phase; and externally displaying and/or outputting a combination of data recalculated in the step of verifying calculated data and the data used in the step of detecting Io1, Vf, and of each phase.

The steps common to those of FIG. 23 are omitted, and the step of calculating an in-phase component zero value of each phase 150 will be described. Active component leakage current generated by insulation resistors Ir, with which the active component leakage current value Ir becomes zero, is calculated for each of three phases. This value is calculated to understand that how much reactive component leakage current Ic flows at the secondary side of the zero-phase current converter 10 if the active component leakage current Ir generated by the insulation resistors becomes zero. Describing it easily, it is to make active component leakage currents generated by the insulation resistors Ir be balanced in all three phases. However, a predetermined value that is slightly larger than the zero value can be selected.

An active component leakage current value of R-phase is calculated first to find out the phase of active component zero leakage current that should be additionally flown through the primary winding of the zero-phase current transformer 10 to make Io1rr zero, i.e., the value of Equation 2 becomes zero. Io1rr and Io1cr of R-phase, Io1ᵣₛ and Io1cs of S-phase, and Io1rt and Io1_{ct} of T-phase described in the above example and stored in the memory unit 86 are read. Then, Irs′, and Irt′ values are calculated so that the in-phase active component leakage current of R-phase becomes zero, i.e., the value of Equation 2 becomes zero. If the Irr′, Irs′, and Irt′ values are put into Equation 3 and a 90° phase-shifted component leakage current value Io1cr′ of R-phase is calculated, Io1cr′ becomes as shown in Equation 6. If the Irr′, Irs′, and Irt′ values are put into Equation 2 and an in-phase component leakage current value Io1rr′ of R-phase is calculated, Io1rr′ becomes as shown in Equation 7.

$$\begin{matrix}If {Irr}^{′} is applied , & \\ Icr - \frac{Ics}{2} - \frac{Ict}{2} + \frac{\sqrt{3}}{2} Irs - \frac{\sqrt{3}}{2} Irt = 73.8 \\ If {lrs}^{′} is applied , \\ Icr - \frac{Ics}{2} - \frac{Ict}{2} + \frac{\sqrt{3}}{2} ( Irs + {Irs}^{′} ) - \frac{\sqrt{3}}{2} Irt = 73.8 + \frac{\sqrt{3} {Irs}^{′}}{2} \\ If {lrt}^{′} is applied , \\ Icr - \frac{Ics}{2} - \frac{Ict}{2} + \frac{\sqrt{3}}{2} Irs - \frac{\sqrt{3}}{2} ( Irt + {Irt}^{′} ) = 73.8 - \frac{\sqrt{3} {Irt}^{′}}{2} & < Equation 6 > \\ If {lrr}^{′} is applied , & \\ ( Irr - {Irr}^{′} ) - \frac{Irs}{2} - \frac{Irt}{2} - \frac{\sqrt{3}}{2} Ics + \frac{\sqrt{3}}{2} Ict = - 19.5 + {Irr}^{′} \\ If {lrs}^{′} is applied , \\ Irr - \frac{( Irs + {Irs}^{′} )}{2} - \frac{Irt}{2} - \frac{\sqrt{3}}{2} Ics + \frac{\sqrt{3}}{2} Ict = - 19.5 + \frac{{Irs}^{′}}{2} \\ If {lrt}^{′} is applied , \\ Irr - \frac{Irs}{2} - \frac{( Irt + {Irt}^{′} )}{2} - \frac{\sqrt{3}}{2} Ics + \frac{\sqrt{3}}{2} Ict = - 19.5 + \frac{{Irt}^{′}}{2} & < Equation 7 >\end{matrix}$$

Since the value of Equation 7 becomes zero when Irr′=19.5, Irs′=−39, and Irt′=−39, if the values are put into Equation 6 respectively, the zero-phase leakage currents become 0+j73.8, 0+j40, and 0+j107.6, and the Irr′, Irs′, and Irt′ values of R-phase are stored in the memory unit 86.

Next, if zero-phase leakage currents of S-phase and R-phase are respectively calculated in the same manner as that of R-phase, following results will be obtained.

The active component leakage current value of S-phase becomes zero when Irr′=147.3, Irs′=−73.7, and Irt′=147.3, and if the values are put as described above, the zero-phase leakage currents become 0−j147.5, 0−j20, and 0+j107.5, and the Irr′, Irs′, and Irt′ values of S-phase are stored in the memory unit 86.

The active component leakage current value of T-phase becomes zero when Irr′=−108.3, Irs′=−108.3, and Irt′=54.1, and if the values are put as described above, the zero-phase leakage currents become 0−j147.5, 0+j40.0, and 0−j53.8, and the Irr′, Irs′, and Irt′ values of T-phase are stored in the memory unit 86.

Next, the step of verifying the calculated data 160 is described.

Active component zero leakage current Ir′ values calculated and stored in the memory unit 86 in the step of calculating an in-phase component zero value of each phase 150, with which the active component leakage current Ir of each phase becomes zero, are read. Then, using the zero-phase leakage current for R-phase voltage Io=19.5+j73.8 mA, the zero-phase leakage current for S-phase voltage Io=73.6−j20.0 mA, and the zero-phase leakage current for T-phase voltage Io=−54.1−j53.8 mA, which are calculated in the step of calculating an in-phase and a phase-shifted components of the leakage current component Io1 of each phase 130, it is examined that an in-phase component and a 90° phase-shifted component of which phase is large or small.

Examining a large value first, since the largest in-phase component is +73.6 of S-phase, if the in-phase component of S-phase is added + (plus), the active component leakage current of S-phase Irs or the reactive component leakage current of R-phase Icr is larger than the active component leakage current of T-phase Irt, the active component leakage current of R-phase Irr, or the reactive component leakage current of T-phase Ict. Since the largest 90° phase-shifted component is +73.8 of R-phase, if the 90° phase-shifted component of R-phase is added + (plus), the reactive component leakage current of R-phase Icr or the active component leakage current of S-phase Irs is larger than the reactive component leakage current of S-phase Ics, the reactive component leakage current of T-phase Ict, or the active component leakage current of T-phase Irt. Therefore, this case satisfies two conditions, and thus although a small value are examined, among the zero-phase leakage current components flowing between the power line 3 and the ground, active component leakage current generated by insulation resistors is largest in S-phase, and reactive component leakage current generated by electrostatic capacitance is largest in R-phase. Accordingly, in the cases where active component leakage current becomes zero, a condition corresponding to R-phase where 90° phase-shifted component leakage current of R-phase is plus + is Irs′=39 with which the active component leakage current of R-phase becomes zero. At this point, the 90° phase-shifted reactive component leakage current of R-phase is +40. Accordingly, it is understood that actual reactive component leakage current of R-phase flowing between the power line 3 and the ground due to the electrostatic capacitance is larger than those of the other phases by +40 mA, and actual active component leakage current of S-phase flowing between the power line 3 and the ground due to the insulation resistors is larger than those of the other phases by +39 mA.

3) A Case of Calculating an Active Component Zero Leakage Current Value and a Reactive Component Zero Leakage Current Value when the Reactive Component Leakage Current Ic is Zero and the Active Component Leakage Current Ir is Zero

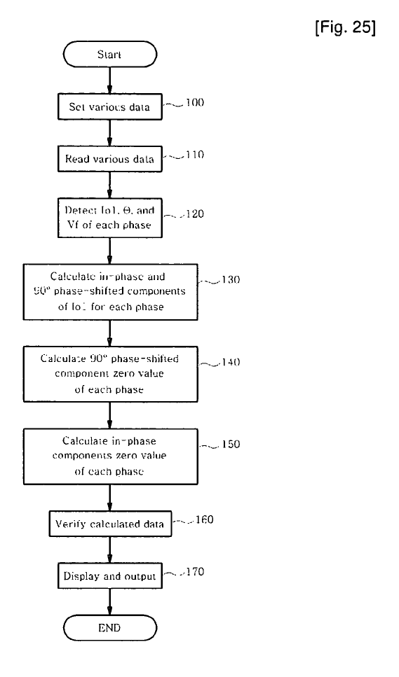

A third insulation detecting method of the present invention shown in FIG. 25 is a combined method of FIGS. 23 and 24. The steps already shown in FIGS. 23 and 24 will not be described, and the step of calculating a 90° phase-shifted component zero value of each phase 140 is described.

A reactive leakage current value generated by electrostatic capacitance, with which a reactive component leakage current value becomes zero, is calculated for each of three phases. This value is calculated to understand that active component leakage current of which component flows at the secondary side of the zero-phase current converter 10 if the reactive component leakage current Ic generated by the electrostatic capacitance becomes zero. Describing it easily, it is to make reactive component leakage currents generated by the electrostatic capacitances be balanced in all three phases. A reactive component leakage current value of R-phase is calculated first to find out the phase and magnitude of reactive component zero leakage current Ic′ that should be additionally flown through the primary winding of the zero-phase current transformer 10 to make Io1cr zero, i.e., the value of Equation 3 becomes zero. Io1rr and Io1cr of R-phase, Io1rs and lobes of S-phase, and Io1rt and Io1_{ct} of T-phase described in the above example and stored in the memory unit 86 are read. Then, Icr′, Ics′, and Ict′ values are calculated so that the 90° phase-shifted reactive component leakage current of R-phase becomes zero, i.e., the value of Equation 3 becomes zero. If the Icr′, Ics′, and Ict′ values are put into Equation 2 and an in-phase component leakage current value Io1rr′ of R-phase is calculated, Io1rr′ becomes as shown in Equation 8. If the Icr′, Ics′, and Ict′ values are put into Equation 3 and a 90° phase-shifted component leakage current value Io1cr′ of R-phase is calculated, Io1cr′ becomes as shown in Equation 9.

$$\begin{matrix}If {Icr}^{′} is applied , & \\ Irr - \frac{Irs}{2} - \frac{Irt}{2} - \frac{\sqrt{3}}{2} Ics + \frac{\sqrt{3}}{2} Ict = - 19.5 \\ If {lcs}^{′} is applied , \\ Irr - \frac{Irs}{2} - \frac{Irt}{2} - \frac{\sqrt{3}}{2} ( Ics + {Ics}^{′} ) + \frac{\sqrt{3}}{2} Ict = - 19.5 - \frac{\sqrt{3}}{2} {Ics}^{′} \\ If {lcs}^{′} is applied , \\ Irr - \frac{Irs}{2} - \frac{Irt}{2} - \frac{\sqrt{3}}{2} Ics + \frac{\sqrt{3}}{2} ( Ict + {Ict}^{′} ) = - 19.5 + \frac{\sqrt{3}}{2} {Ict}^{′} & < Equation 8 > \\ If {lcr}^{′} is applied , & \\ ( Icr + {Icr}^{′} ) - \frac{Ics}{2} - \frac{Ict}{2} + \frac{\sqrt{3}}{2} Irs - \frac{\sqrt{3}}{2} Irt = 73.8 + {Icr}^{′} \\ If {lcs}^{′} is applied , \\ Icr - \frac{( Ics + {Ics}^{′} )}{2} - \frac{Ict}{2} + \frac{\sqrt{3}}{2} Irs - \frac{\sqrt{3}}{2} Irt = 73.8 - \frac{{Ics}^{′}}{2} \\ If {lct}^{′} is applied , \\ Icr - \frac{Ics}{2} - \frac{( Ict + {Ict}^{′} )}{2} + \frac{\sqrt{3}}{2} Irs - \frac{\sqrt{3}}{2} Irt = 73.8 - \frac{{Ict}^{′}}{2} & < Equation 9 >\end{matrix}$$

Since the value of Equation 9 becomes zero when Icr′=−73.8, Ics′=147.6, and Ict′=147.6, if the values are put into Equation 8 respectively, the zero-phase leakage currents become −19.5+j0, −147.3+j0, and 108.3+j0, and the Icr′, Ics′, and Ict′ values of R-phase are stored in the memory unit 86.

Next, if zero-phase leakage currents of S-phase and R-phase are respectively calculated in the same manner as that of R-phase, following results will be obtained.

The reactive component leakage current value of S-phase becomes zero when Icr′=−40.0, Ics′=20.0, and Ict′=−40.0, and if the values are put as described above, the zero-phase leakage currents become 39.9+j0, 73.6+j0, and 108.3+j0, and the Icr′, Ics′, and Ict′ values of S-phase are stored in the memory unit 86.

The reactive component leakage current value of T-phase becomes zero when Icr′=−107.5, and Ics′=−53.8, and if the values are put as described above, the zero-phase leakage currents become 39.0+j0, −147.3+j0, and −54.1+j0, and the Icr′, Ics′, and Ict′ values of T-phase are stored in the memory unit 86.

Next, the step of calculating an in-phase component zero value of each phase 150 is described.

In a method almost similar to the step of calculating a 90° phase-shifted component zero value of each phase 140, an active component leakage current generated by insulation resistors, with which the active component leakage current value becomes zero, is calculated for each of three phases. This value is calculated to understand that how much reactive component leakage current flows at the secondary side of the zero-phase current converter 10 if the active component leakage current generated by the insulation resistors becomes zero. Describing it easily, it is to make active component leakage currents generated by the insulation resistors Ir be balanced in all three phases. An active component leakage current value of R-phase is calculated first to find out the phase of active component zero leakage current Ir′ that should be additionally flown through the primary winding of the zero-phase current transformer 10 to make Io1rr zero, i.e., the value of Equation 2 becomes zero. Io1rr and Io1cr of R-phase, Io1ᵣₛ and to of S-phase, and Io1rt and Io1_{ct} of T-phase described in the above example and stored in the memory unit 86 are read. Then, Irr′, Irs′, and Irt′ values are calculated so that the in-phase active component leakage current of R-phase becomes zero, i.e., the value of Equation 2 becomes zero. If the Irr′, Irs′, and Irt′ values are put into Equation 3 and a 90° phase-shifted component leakage current value Io1cr′ of R-phase is calculated, Io1cr′ becomes as shown in Equation 10. If the Irr′, Irs′, and Irt′ values are put into Equation 2 and an in-phase component leakage current value Io1rr′ of R-phase is calculated, Io1rr′ becomes as shown in Equation 11.

$$\begin{matrix}If {Irr}^{′} is applied , & \\ Icr - \frac{Ics}{2} - \frac{Ict}{2} + \frac{\sqrt{3}}{2} Irs - \frac{\sqrt{3}}{2} Irt = 73.8 \\ If {lrs}^{′} is applied , \\ Icr - \frac{Ics}{2} - \frac{Ict}{2} + \frac{\sqrt{3}}{2} ( Irs + {Irs}^{′} ) - \frac{\sqrt{3}}{2} Irt = 73.8 + \frac{\sqrt{3} {Irs}^{′}}{2} \\ If {lrt}^{′} is applied , \\ Icr - \frac{Ics}{2} - \frac{Ict}{2} + \frac{\sqrt{3}}{2} Irs - \frac{\sqrt{3}}{2} ( Irt + {Irt}^{′} ) = 73.8 - \frac{\sqrt{3} {Irt}^{′}}{2} & < Equation 10 > \\ If {lrr}^{′} is applied , & \\ ( Irr - {Irr}^{′} ) - \frac{Irs}{2} - \frac{Irt}{2} - \frac{\sqrt{3}}{2} Ics + \frac{\sqrt{3}}{2} Ict = - 19.5 + {Irr}^{′} \\ If {lrs}^{′} is applied , \\ Irr - \frac{( Irs + {Irs}^{′} )}{2} - \frac{Irt}{2} - \frac{\sqrt{3}}{2} Ics + \frac{\sqrt{3}}{2} Ict = - 19.5 + \frac{{Irs}^{′}}{2} \\ If {lrt}^{′} is applied , \\ Irr - \frac{Irs}{2} - \frac{( Irt + {Irt}^{′} )}{2} - \frac{\sqrt{3}}{2} Ics + \frac{\sqrt{3}}{2} Ict = - 19.5 + \frac{{Irt}^{′}}{2} & < Equation 11 >\end{matrix}$$

Since the value of Equation 11 becomes zero when Irr′=19.5, Irs′=−39, and Irt′=−39, if the values are put into Equation 10 respectively, the zero-phase leakage currents become 0+j73.8, 0+j40, and 0+j107.6, and the Irr′, Irs′, and Irt′ values of R-phase are stored in the memory unit 86.

Next, if zero-phase leakage currents of S-phase and R-phase are respectively calculated in the same manner as that of R-phase, following results will be obtained.

The active component leakage current value of S-phase becomes zero when Irr′=147.3, Irs′=−73.7, and Irt′=147.3, and if the values are put as described above, the zero-phase leakage currents become 0−j147.5, 0−j20, and 0+j107.5, and the Irr′, Irs′, and Irt′ values of S-phase are stored in the memory unit 86.

The active component leakage current value of T-phase becomes zero when Irr′=−108.3, Irs′=−108.3, and Irt′=54.1, and if the values are put as described above, the zero-phase leakage currents become 0−j147.5, 0+j40.0, and 0−j53.8, and the Irr′, Irs′, and Irt′ values of T-phase are stored in the memory unit 86.

Next, the step of verifying the calculated data 160 is performed. Reactive component zero leakage current Ic′ values calculated and stored in the memory unit 86 in the step of calculating a 90° phase-shifted component zero value of each phase 140, with which the reactive component leakage current of each phase becomes zero, are combined by each case with Ir′ values calculated and stored in the memory unit 86 in the step of calculating an in-phase component zero value of each phase 150, with which the active component leakage current of each phase becomes zero, and a combination where an Io value corresponding to the zero-phase leakage current becomes zero is searched. The Ic′ values and the Ir′ values are combined case by case, and the recalculated Io value becomes zero. In this case, since the leakage current generated by the insulation resistor of S-phase is the largest, a selected combination is Irs′=−39.0 and Icr′=−40.0. Analyzing the meaning of the result, the active component leakage current generated by the insulation resistor of S-phase is larger than those of R-phase and T-phase by about 39 mA, and the reactive component leakage current generated by the electrostatic capacitance of R-phase is larger than those of S-phase and T-phase by about 40 mA. That is, it is understood that the insulation resistance of S-phase is the lowest, which means poor insulation, and the electrostatic capacitance of R-phase to the ground is the highest.

The step of displaying and outputting a variety of data shown in FIGS. 23 to 25 170 is described.

This is a step of displaying the combinations recalculated in the step of verifying the calculated data 160 and a result of performing the step of detecting Io1, and Viol each phase 120, in which the detected data, such as the active component leakage current Ior=39 mA, reactive component leakage current Ioc=40 mA, zero-phase leakage current Io=76.3 mA, information on a phase where insulation is the most poor (e.g., S-phase in the example described above), information on a phase where the reactive component leakage current generated by electrostatic capacitance is the highest (e.g., T-phase in the example described above), or the like, is displayed on the display unit 84. In addition, insulation resistance R for the active component leakage current Ior=39 mA or electrostatic capacitance C for the reactive component leakage current Ioc=40 mA of the zero-phase voltage between the power line 3 and the ground detected in the step of detecting Io1, and Vf of each phase 120 can also be displayed.

Here, the insulation resistance R can be expressed as shown in Equation 12, and the electrostatic capacitance C can be expressed as shown in Equation 13. In Equations 12 and 13, the voltage amplification coefficient is an amplification-related coefficient of the voltage detecting means 30, and it is assumed that the amplification-related co-efficient of the leakage current detecting means 40 including the zero-phase current transformer 10 is one.

$$\begin{matrix}Insulation resistance ( R ) = \frac{Voltage Amplification Coefficient \times Vf}{Icr} & < Equation 12 > \\ Electrostatic capacitance ( C ) = \frac{Ic}{\begin{matrix}2 π f \times \\ Voltage Amplification Coefficient \times Vf\end{matrix}} & < Equation 13 >\end{matrix}$$

In addition, using various types of communication methods (RS-232, RS-485, RS-422, code division multiple access (CDMA), or powerline communication), the data described above can be outputted to outside through the communication unit 90.

In addition, a variety of data described above is compared with an alarm setting value that is previously stored in the memory unit 86, inputted through the input unit 82, or received through the communication unit 90. If the alarm setting value is larger than the active leakage current Ior or Ir, or smaller than the insulation resistance R, a warning alarm can be displayed on the display unit 84 or outputted through the communication unit 90.

### Second Embodiment

A second embodiment of the insulation detecting apparatus of the present invention is described below.

FIGS. 23 to 25 are flowcharts illustrating an insulation detecting apparatus and an insulation detecting method that can be used in a second embodiment in the same manner as the first embodiment described referring to FIGS. 10 and 11.

FIG. 10 shows a block diagram of the insulation detecting apparatus used in FIGS. 2 to 7 according to a second embodiment of the insulation detecting apparatus.

The insulation detecting apparatus 20 of the present invention comprises a voltage detecting means 30 for detecting a voltage component between the power line 3 and the ground, transforming the detected voltage component into voltage of a certain magnitude, and extracting a frequency component lower than a certain frequency or a frequency component of a commercial frequency band from a voltage component of a sequentially selected phase; a leakage current detecting means 40 for converting the zero-phase leakage current Io component, which is detected at the secondary side of the zero-phase current transformer 10 for detecting zero-phase leakage current Io between the power line 3 including a load 4 and the ground, into a voltage component, amplifying the converted voltage component, and extracting a frequency component lower than a certain frequency or a frequency component of a commercial frequency band; a phase comparing means 50 for comparing each of three phases of an output value of the voltage detecting means 30 with a phase of an output value of the leakage current detecting means 40; an analog-to-digital conversion unit 60 for converting an analog component of the output value of the leakage current detecting means 40 to a digital component; an operation controller 70 having an operation and control function for reading and outputting a variety of data; an input-output means 80 for inputting and displaying a variety of data; and a communication unit 90 for remotely controlling the insulation detecting apparatus from outside. The input-output means 80 includes an input unit 82, a display unit 84, and a memory unit 86.

Referring to FIG. 11, the voltage detecting means 30 for detecting a three phase voltage component of the power line 3 including a load comprises a voltage detecting unit 31 for transforming the three phase voltage component detected by the voltage detection line 12, 13, and 14 into voltage of a certain magnitude, a phase selection unit 32 for sequentially selecting a voltage component of a phase from the three phase voltage component transformed by the voltage detecting unit 31 in response to an RST voltage control signal outputted from the operation controller 70, and a voltage filter unit 33 for extracting a frequency component lower than a certain frequency or a frequency component of a commercial frequency band from the voltage component of the phase selected by the phase selection unit 32. The leakage current detecting means 40 comprises a current-to-voltage conversion unit 41 for converting leakage current component, which is detected at the secondary side of the zero-phase current transformer 10 for detecting the zero-phase leakage current Io between the power line 3 including the load 4 and the ground, into a voltage component, an amplification unit 42 for amplifying the zero-phase leakage current component Io converted by the current-to-voltage conversion unit 41, and a current filter unit 43 for extracting a frequency component lower than a certain frequency or a frequency component of a commercial frequency band from a leakage current component corresponding to the zero-phase leakage current Io component amplified by the amplification unit 42.

The phase comparing means 50 includes a voltage component waveform shaping unit 51 for shaping the waveform of the voltage component of each of three phases outputted from the voltage detecting means 30, a current component waveform shaping unit 52 for shaping the waveform of the leakage current component corresponding to the zero-phase leakage current Io component outputted from the leakage current detecting means 40, and a phase difference detecting unit 53 for detecting a phase difference of an output of the current component waveform shaping unit 52 from an output of the voltage component waveform shaping unit 51. Only one output value of the leakage current detecting means 40 is inputted into the analog-to-digital conversion unit 60 in FIG. 10. However, two analog components, i.e., the output value of the leakage current detecting means 40 and the output value of the voltage detecting means 30, are inputted into the analog-to-digital conversion unit 60 in FIG. 11.

The voltage component value of the power line 3 is read, and whether the read voltage component is used for calculating insulation resistance, as well as calculating a leakage current value, or whether only the leakage current value is calculated and the insulation resistance is not calculated will be different among embodiments. However, in an embodiment of the present invention, the insulation resistance will be calculated in order to express a variety of values for monitoring insulation conditions.

Hereinafter, a second embodiment of the insulation detecting apparatus 20 shown FIG. 11 and a flowchart illustrating an operational flow of the insulation detecting apparatus 20 will be described in detail.

As shown in FIGS. 11 and 23, on the main flow stored in the memory unit 86 of the insulation detecting apparatus 20, the input unit 82 sets a variety of data used in the insulation detecting apparatus 20 using a constitutional component such as a keypad or a switch 100, in which the input unit has a function for setting a variety of data, e.g., a number address, an alarm setting value, and the like of each insulation detecting apparatus 20 if a plurality of insulation detecting apparatuses 20 is installed. Next, a read operation is performed on a variety of data set by the input unit 82, previously stored in the memory unit 86, or inputted from a remote external site through the communication unit 90 110.

If the step of detecting Io1, Vf, and of each phase 120 is performed, the zero-phase leakage current component to detected at the secondary side of the zero-phase current transformer 10 as shown in FIGS. 10 and 11 is converted into a voltage component by the current-to-voltage conversion unit 41 that converts current to voltage and amplified by the amplification unit 42. Then, a current component Io1 corresponding to the zero-phase leakage current from which a frequency component lower than a certain frequency or a frequency component of a commercial frequency band is extracted by the current filter unit 43 is outputted to the analog-to-digital conversion unit 60 and the phase comparing means 50. The component Io1 value corresponding to the zero-phase leakage current inputted into the analog-to-digital conversion unit 32 (60) is converted into a digital value, and the operation controller 70 reads and stores the digital value into the memory unit 86.

Then, the voltage detecting unit 31 used in the embodiments shown in FIGS. 14 to 21 splits the voltage component of each of three phases between the power line 3 and the ground inputted through the voltage detection lines 12, 13, and 14 into voltages that can be used in the insulation detecting apparatus 20, using resistors, condensers, a transformer, the 120° phase shift unit 311, or the 240° phase shift unit 312.

In order to detect a voltage component of each of three phases outputted from the voltage detecting unit 31, if the switch sw1 in the phase selection unit 32 is connected to terminal a in response to an RST voltage control signal for selecting R-phase received from the operation controller 70, the voltage component of R-phase is inputted into the voltage filter unit 33. The voltage component Vf value (Vf_r of R-phase), i.e., the voltage component of R-phase selected by the phase selection unit 32 from which a frequency component lower than a certain frequency or a frequency component of a commercial frequency band is extracted by the voltage filter unit 33, is outputted to the phase comparing means 50 and the analog-to-digital conversion unit 60. The voltage component Vf_r value to the ground inputted into the analog-to-digital conversion unit 60 is converted into a digital value, and the operation controller 70 reads and stores the digital value into the memory unit 86. Using the value of the voltage component Vf_r to the ground inputted into the phase comparing means 50, whose waveform is shaped by the voltage component waveform shaping unit 51, and the value of the leakage current component Io1 corresponding to the zero-phase leakage current component outputted from the leakage current detecting means 40, whose waveform is shaped by the current component waveform shaping unit 52, the phase difference detecting unit 53 detects a phase difference between the voltage component outputted from the voltage component waveform shaping unit 51 and the one leakage current component outputted from the current component waveform shaping unit 52, i.e., a phase difference r of the leakage current component Io1 for the voltage component Vf_r of R-phase, and the operation controller 70 reads and stores the phase difference into the memory unit 86.

Next, if the switch sw1 in the phase selection unit 32 is connected to terminal b in response to an RST voltage control signal for selecting S-phase received from the operation controller 70, the voltage component of S-phase is inputted into the voltage filter unit 33. The voltage component Vf value (Vf_s of S-phase), i.e., the voltage component of S-phase selected by the phase selection unit 32 from which a frequency component lower than a certain frequency or a frequency component of a commercial frequency band is extracted by the voltage filter unit 33, is outputted to the phase comparing means 50 and the analog-to-digital conversion unit 60. The voltage component Vf_s value to the ground inputted into the analog-to-digital conversion unit 60 is converted into a digital value, and the operation controller 70 reads and stores the digital value into the memory unit 86. Using the value of the voltage component Vf_s to the ground inputted into the phase comparing means 50, whose waveform is shaped by the voltage component waveform shaping unit 51, and the value of the leakage current component Io1 corresponding to the zero-phase leakage current component outputted from the leakage current detecting means 40, whose waveform is shaped by the current component waveform shaping unit 52, the phase difference detecting unit 53 detects a phase difference between the voltage component outputted from the voltage component waveform shaping unit 51 and the one leakage current component outputted from the current component waveform shaping unit 52, i.e., a phase difference s of the leakage current component Io1 for the voltage component Vf_s of S-phase, and the operation controller 70 reads and stores the phase difference into the memory unit 86.

Next, if the switch sw1 in the phase selection unit 32 is connected to terminal c in response to an RST voltage control signal for selecting T-phase received from the operation controller 70, the voltage component of T-phase is inputted into the voltage filter unit 33. The voltage component Vf value (Vf_t of T-phase), i.e., the voltage component of T-phase selected by the phase selection unit 32 from which a frequency component lower than a certain frequency or a frequency component of a commercial frequency band is extracted by the voltage filter unit 33, is outputted to the phase comparing means 50 and the analog-to-digital conversion unit 60. The voltage component Vf_t value to the ground inputted into the analog-to-digital conversion unit 60 is converted into a digital value, and the operation controller 70 reads and stores the digital value into the memory unit 86. Using the value of the voltage component Vf_t to the ground inputted into the phase comparing means 50, whose waveform is shaped by the voltage component waveform shaping unit 51, and the value of the leakage current component Io1 corresponding to the zero-phase leakage current component outputted from the leakage current detecting means 40, whose waveform is shaped by the current component waveform shaping unit 52, the phase difference detecting unit 53 detects a phase difference between the voltage component outputted from the voltage component waveform shaping unit 51 and the one leakage current component outputted from the current component waveform shaping unit 52, i.e., a phase difference t of the leakage current component Io1 for the voltage component Vf_t of T-phase, and the operation controller 70 reads and stores the phase difference into the memory unit 86.

An example of calculating the voltage component Vf, leakage current component Io1, and phase difference described above is described. For the convenience of explanation, it is assumed that the amplification-related coefficient of the leakage current detecting means 40 including the zero-phase current transformer 10 is one, and the amplification-related coefficient of the voltage detecting means 30 is 0.001 (i.e., 1/1000).

The voltage between the three-phase power line 3 and the ground is 220V, and the frequency is 60 Hz. The leakage currents flowing through the insulation resistors between the three-phase power line and the ground are respectively Irr=1 mA for R-phase, Irs=40 mA for S-phase, and Irt=1 mA for T-phase. The leakage currents flowing through the electrostatic capacitances between the three-phase power line and the ground are respectively Icr=60 mA for R-phase, Ics=20 mA for S-phase, and Ict=20 mA for T-phase.

The values detected and stored in the memory unit 86 in the step of detecting the voltage component Vf, leakage current component Io1, and phase difference 120 are such that Io1 is 76.3 mA, Vf_r, Vf_s, and Vf_t are 220 mV respectively, r is 104.8, s is −15.2, and t is −135.2.

Next, if the step of calculating an in-phase and a 90° phase-shifted components of the leakage current component Io1 of each phase 130 is performed, the leakage current component Io1 and the phase differences r, s, and t detected and stored in the memory unit 86 in the step of detecting the voltage component Vf, leakage current component Io1, and phase difference 120 are read. For each of three phases, an in-phase component cos value and a 90° phase-shifted component sin value for the voltage of the leakage current Io1 corresponding to the zero-phase leakage current are calculated and stored in the memory unit 86. Describing more specifically, the in-phase component leakage current of R-phase Io1rr is Io1×cos r, the 90° phase-shifted component leakage current of R-phase Io1cr is Io1×sin r, the in-phase component leakage current of S-phase Io1ᵣₛ is Io1×cos s, the 90° phase-shifted component leakage current of S-phase Io1cs is Io1×sin s, the in-phase component leakage current of T-phase Io1rt is Io1×cos t, and the 90° phase-shifted component leakage current of T-phase Io1_{ct} is Io1×sin t.

Substituting the values described in the above example and approximately calculating the zero-phase leakage currents, Io1rr=−19.5 mA, Io1cr=73.8 mA, Io1ᵣₛ=73.6 mA, Io1cs=−20.0 mA, Io1rt=−54.1 mA, and Io1_{ct}=−53.8 mA, and therefore, the zero-phase leakage current Io for the R-phase voltage is −19.5+j73.8 mA, the zero-phase leakage current to for the S-phase voltage is 73.6−j20 mA, and the zero-phase leakage current Io for T-phase voltage is −54.1−j53.8 mA.

For the values calculated above, a functional relation between an in-phase component leakage current value for voltage and a 90° phase-shifted component leakage current value for voltage of each of three phases will be described first. The zero-phase leakage current to component flowing between the power line 3 including the load 4 and the ground can be expressed as shown in Equation 14. Next, the zero-phase leakage current for a three phase voltage component shown in Equation 14 is converted to a voltage component value of R-phase, and a value corresponding to the zero-phase leakage current component of a voltage component that is in-phase with the R-phase voltage, i.e., Io1rr, is expressed as shown in Equation 15, and a value corresponding to the zero-phase leakage current component of the voltage component that is 90° phase-shifted from the R-phase voltage, i.e., Io1cr, is expressed as shown in Equation 16.

$$\begin{matrix}\begin{matrix}{Io}^{°} = \frac{{V}_{{R}^{°}}}{Rr} + \frac{{V}_{{S}^{°}}}{Rs} + \frac{{V}_{{T}^{°}}}{Rt} + \\ j ( ω Cr {V}_{{R}^{°}} + ω Cs {V}_{{S}^{°}} + ω Ct {V}_{{T}^{°}} ) \\ = {Irr}^{°} + {Ics}^{°} + {Ict}^{°} + j ( {Icr}^{°} + {Ics}^{°} + {Ict}^{°} )\end{matrix} \\ Here , V and I are vector functions . & < Equation 14 > \\ Irr - \frac{Irs}{2} - \frac{Irt}{2} - \frac{\sqrt{3}}{2} Ics + \frac{\sqrt{3}}{2} Ict \\ Here , I is a real value . & < Equation 15 > \\ Icr - \frac{Ics}{2} - \frac{Ict}{2} + \frac{\sqrt{3}}{2} Irs - \frac{\sqrt{3}}{2} Irt \\ Here , I is a real value . & < Equation 16 >\end{matrix}$$

The relational expression between the in-phase component leakage current and the 90° phase-shifted component leakage current of S-phase and T-phase is that they respectively have 120° and −120° phase differences from the in-phase component leakage current and the 90° phase-shifted component leakage current of R-phase.

As shown in Equations 15 and 16, it is understood that the in-phase component leakage current of R-phase includes not only active component leakage current Irr flowing due to the insulation resistance of R-phase, but also active component leakage currents Irs and Irt flowing due to the insulation resistances of S-phase and T-phase and reactive component leakage currents Ics and Ict flowing due to the electrostatic capacitances of S-phase and T-phase. The 90° phase-shifted component leakage current of R-phase includes not only reactive component leakage current Icr flowing due to the electrostatic capacitance of R-phase, but also reactive component leakage currents Ics and Ict flowing due to the electrostatic capacitances of S-phase and T-phase and active component leakage currents Irs and Irt flowing due to the insulation resistances of S-phase and T-phase. Then, it can be conjectured from Equations 15 and 16 that an insulation state cannot be correctly obtained by a conventional method of detecting zero-phase leakage current Io generated by a zero-phase current transformer.

1) The step of calculating a 90° phase-shifted component zero value of each phase 140 is described referring to FIG. 23.

A reactive component leakage current value generated by electrostatic capacitance with which a reactive component leakage current becomes zero is calculated for each of three phases. This value is calculated to understand that active component leakage current of which component flows at the secondary winding of the zero-phase current converter 10 if the reactive component leakage current Ic generated by the electrostatic capacitance becomes zero. Describing it easily, it is to make reactive component leakage currents generated by electrostatic capacitances be balanced in all three phases. A reactive component leakage current value of R-phase is calculated first to find out the phase and magnitude of reactive component zero leakage current Ic′ that should be additionally flown through the primary winding of the zero-phase current transformer 10 to make Io1cr zero, i.e., the value of Equation 16 becomes zero. Io1rr and Io1cr of R-phase, Io1ᵣₛ and Io1cs of S-phase, and Io1rt and Io1_{ct} of T-phase described in the above example and stored in the memory unit 86 are read. Then. Icr′, Ics′, and Ict′ values are calculated so that the 90° phase-shifted reactive component leakage current of R-phase becomes zero, i.e., the value of Equation 3 becomes zero. If the Icr′, Ics′, and Ict′ values are put into Equation 15 and an in-phase component leakage current value Io1rr′ of R-phase is calculated, Io1rr′ becomes as shown in Equation 17. If the Icr′, Ics′, and Ict′ values are put into Equation 16 and a 90° phase-shifted component leakage current value Io1cr′ of R-phase is calculated, Io1cr′ becomes as shown in Equation 18.

$$\begin{matrix}If {Icr}^{′} is applied , & \\ Irr - \frac{Irs}{2} - \frac{Irt}{2} - \frac{\sqrt{3}}{2} Ics + \frac{\sqrt{3}}{2} Ict = - 19.5 \\ If {lcs}^{′} is applied , \\ Irr - \frac{Irs}{2} - \frac{Irt}{2} - \frac{\sqrt{3}}{2} ( Ics + {Ics}^{′} ) + \frac{\sqrt{3}}{2} Ict = - 19.5 - \frac{\sqrt{3}}{2} {Ics}^{′} \\ If {lct}^{′} is applied , \\ Irr - \frac{Irs}{2} - \frac{Irt}{2} - \frac{\sqrt{3}}{2} Ics + \frac{\sqrt{3}}{2} ( Ict + {Ict}^{′} ) = - 19.5 + \frac{\sqrt{3}}{2} {Ict}^{′} & < Equation 17 > \\ If {lcr}^{′} is applied , & \\ ( Icr + {Icr}^{′} ) - \frac{Ics}{2} - \frac{Ict}{2} + \frac{\sqrt{3}}{2} Irs - \frac{\sqrt{3}}{2} Irt = 73.8 + {Icr}^{′} \\ If {lcs}^{′} is applied , \\ Icr - \frac{( Ics + {Ics}^{′} )}{2} - \frac{Ict}{2} + \frac{\sqrt{3}}{2} Irs - \frac{\sqrt{3}}{2} Irt = 73.8 - \frac{{Ics}^{′}}{2} \\ If {lct}^{′} is applied , \\ Icr - \frac{Ics}{2} - \frac{( Ict + {Ict}^{′} )}{2} + \frac{\sqrt{3}}{2} Irs - \frac{\sqrt{3}}{2} Irt = 73.8 - \frac{{Ict}^{′}}{2} & < Equation 18 >\end{matrix}$$

Since the value of Equation 18 becomes zero when Icr′=−73.8, Ics′=147.6, and Ict′=147.6, if the values are put into Equation 17 respectively, the zero-phase leakage currents become −19.5+j0, −147.3+j0, and 108.3+j0, and the Icr′, Ics′, and Ict′ values of R-phase are stored in the memory unit 86.

Next, if zero-phase leakage currents of S-phase and R-phase are respectively calculated in the same manner as that of R-phase, following results will be obtained.

The reactive component leakage current value of S-phase becomes zero when Icr′=−40.0, Ics′=20.0, and Ict′=−40.0, and if the values are put as described above, the zero-phase leakage currents become 39.9+j0, 73.6+j0, and 108.3+j0, and the Icr′, and Ict′ values of S-phase are stored in the memory unit 86.

The reactive component leakage current value of T-phase becomes zero when Icr′=−107.5, and Ic=53.8, and if the values are put as described above, the zero-phase leakage currents become 39.0+j0, −147.3+j0, and −54.1+j0, and the Icr′, Ics′, and Ict′ values of T-phase are stored in the memory unit 86.

Next, the step of verifying the calculated data 160 is described.

Reactive component zero leakage current Ic′ values calculated and stored in the memory unit 86 in the step of calculating a 90° phase-shifted component zero value of each phase 140, with which the reactive component leakage current of each phase becomes zero, are read. Then, using the zero-phase leakage current for R-phase voltage Io=19.5+j73.8 mA, the zero-phase leakage current for S-phase voltage Io=73.6−j20.0 mA, and the zero-phase leakage current for T-phase voltage Io=−54.1−j53.8 mA, which are calculated in the step of calculating an in-phase and a phase-shifted components of the leakage current component Io1 of each phase 130, it is examined that an in-phase component and a 90° phase-shifted component of which phase is large or small. Examining a large value first, since the largest in-phase component is +73.6 of S-phase, if the in-phase component of S-phase is added + (plus), the active component leakage current of S-phase Irs or the reactive component leakage current of R-phase Icr is larger than the active component leakage current of T-phase Irt, the active component leakage current of R-phase Irr, or the reactive component leakage current of T-phase Ict. Since the largest 90° phase-shifted component is +73.8 of R-phase, if the 90° phase-shifted component of R-phase is added + (plus), the reactive component leakage current of R-phase Icr or the active component leakage current of S-phase Irs is larger than the reactive component leakage current of S-phase Ics, the reactive component leakage current of T-phase Ict, or the active component leakage current of T-phase Irt. Therefore, this case satisfies two conditions, and thus, although a small value is examined, among the zero-phase leakage current components flowing between the power line 3 and the ground, active component leakage current generated by insulation resistors is largest in S-phase, and reactive component leakage current generated by electrostatic capacitance is largest in R-phase. Accordingly, in the cases where reactive component leakage current becomes zero, a condition corresponding to R-phase where in-phase component leakage current of S-phase is plus + is Icr′=40 with which the reactive component leakage current of S-phase becomes zero. At this point, the in-phase active component leakage current of S-phase is +39. Accordingly, it is understood that actual reactive component leakage current of R-phase flowing between the power line 3 and the ground due to the electrostatic capacitance is larger than those of the other phases by +40 mA, and actual active component leakage current of S-phase flowing between the power line 3 and the ground due to the insulation resistors is larger than those of the other phases by +39 mA.

2) The Step of Calculating an In-Phase Component Zero Value of Each Phase 150 is Described

If the step of calculating an in-phase component zero value of each phase 150 is performed, active component leakage current generated by insulation resistors Ir, with which the active component leakage current value Ir becomes zero, is calculated for each of three phases. This value is calculated to understand that how much reactive component leakage current Ic flows at the secondary side of the zero-phase current converter 10 if the active component leakage current Ir generated by the insulation resistors becomes zero.

Describing it easily, it is to make active component leakage currents generated by the insulation resistors Ir be balanced in all three phases. An active component leakage current value of R-phase is calculated first to find out the phase of active component zero leakage current Ir′ that should be additionally flown through the primary winding of the zero-phase current transformer 10 to make Io1rr zero, i.e., the value of Equation 2 becomes zero.

Io1rr and Io1cr of R-phase, Io1ᵣₛ and Io1cs of S-phase, and Io1rt and Io1_{ct} of T-phase described in the above example and stored in the memory unit 86 are read. Then, Irr′, Irs′, and Irt′ values are calculated so that the in-phase active component leakage current of R-phase becomes zero, i.e., the value of Equation 15 becomes zero. If the Irr′, Irs′, and Irt′ values are put into Equation 16 and a 90° phase-shifted component leakage current value Io1cr′ of R-phase is calculated, Io1cr′ becomes as shown in Equation 19. If the Irr′, Irs′, and Irt′ values are put into Equation 15 and an in-phase component leakage current value Io1rr′ of R-phase is calculated, Io1rr′ becomes as shown in Equation 20.

$$\begin{matrix}If {Irr}^{′} is applied , & \\ Icr - \frac{Ics}{2} - \frac{Ict}{2} + \frac{\sqrt{3}}{2} Irs - \frac{\sqrt{3}}{2} Irt = 73.8 \\ If {lrs}^{′} is applied , \\ Icr - \frac{Ics}{2} - \frac{Ict}{2} + \frac{\sqrt{3}}{2} ( Irs + {Irs}^{′} ) - \frac{\sqrt{3}}{2} Irt = 73.8 + \frac{\sqrt{3} {Irs}^{′}}{2} \\ If {lrt}^{′} is applied , \\ Icr - \frac{Ics}{2} - \frac{Ict}{2} + \frac{\sqrt{3}}{2} Irs - \frac{\sqrt{3}}{2} ( Irt + {Irt}^{′} ) = 73.8 - \frac{\sqrt{3} {Irt}^{′}}{2} & < Equation 19 > \\ If {lrr}^{′} is applied , & \\ ( Irr - {Irr}^{′} ) - \frac{Irs}{2} - \frac{Irt}{2} - \frac{\sqrt{3}}{2} Ics + \frac{\sqrt{3}}{2} Ict = - 19.5 + {Irr}^{′} \\ If {lrs}^{′} is applied , \\ Irr - \frac{( Irs + {Irs}^{′} )}{2} - \frac{Irt}{2} - \frac{\sqrt{3}}{2} Ics + \frac{\sqrt{3}}{2} Ict = - 19.5 + \frac{{Irs}^{′}}{2} \\ If {lrt}^{′} is applied , \\ Irr - \frac{Irs}{2} - \frac{( Irt + {Irt}^{′} )}{2} - \frac{\sqrt{3}}{2} Ics + \frac{\sqrt{3}}{2} Ict = - 19.5 + \frac{{Irt}^{′}}{2} & < Equation 20 >\end{matrix}$$

Since the value of Equation 20 becomes zero when Irr′=19.5, Irs′=−39, and Irt′=−39, if the values are put into Equation 19 respectively, the zero-phase leakage currents become 0+j73.8, 0+j40, and 0+j107.6, and the Irr′, Irs′, and Irt′ values of R-phase are stored in the memory unit 86.

Next, if zero-phase leakage currents of S-phase and R-phase are respectively calculated in the same manner as that of R-phase, following results will be obtained.

The active component leakage current value of S-phase becomes zero when Irr′=147.3, Irs′=−73.7, and Irt′=147.3, and if the values are put as described above, the zero-phase leakage currents become 0−j147.5, 0−j20, and 0+j107.5, and the Irr′, Irs′, and Irt′ values of S-phase are stored in the memory unit 86.

The active component leakage current value of T-phase becomes zero when Irr′=−108.3, Irs′=−108.3, and Irt′=54.1, and if the values are put as described above, the zero-phase leakage currents become 0−j147.5, 0+j40.0, and 0−j53.8, and the Irr′, Irs′, and Irt′ values of T-phase are stored in the memory unit 86.

Next, if the step of verifying the calculated data 160 is performed, active component zero leakage current Ir′ values calculated and stored in the memory unit 86 in the step of calculating an in-phase component zero value of each phase 150, with which the active component leakage current Ir of each phase becomes zero, are read. Then, using the zero-phase leakage current for R-phase voltage Io=19.5+j73.8 mA, the zero-phase leakage current for S-phase voltage Io=73.6−j20.0 mA, and the zero-phase leakage current for T-phase voltage Io=−54.1−j53.8 mA, which are calculated in the step of calculating an in-phase and a phase-shifted components of the leakage current component Io1 of each phase 130, it is examined that an in-phase component and a 90° phase-shifted component of which phase is large or small. Examining a large value first, since the largest in-phase component is +73.6 of S-phase, if the in-phase component of S-phase is added + (plus), the active component leakage current of S-phase Irs or the reactive component leakage current of R-phase Icr is larger than the active component leakage current of T-phase Irt, the active component leakage current of R-phase Irr, or the reactive component leakage current of T-phase Ict. Since the largest 90° phase-shifted component is +73.8 of R-phase, if the 90° phase-shifted component of R-phase is added + (plus), the reactive component leakage current of R-phase Irr or the active component leakage current of S-phase Irs is larger than the reactive component leakage current of S-phase Ics, the reactive component leakage current of T-phase Ict, or the active component leakage current of T-phase Irt. Therefore, this case satisfies two conditions, and thus although a small value are examined, among the zero-phase leakage current components flowing between the power line 3 and the ground, active component leakage current generated by insulation resistors is largest in S-phase, and reactive component leakage current generated by electrostatic capacitance is largest in R-phase. Accordingly, in the cases where active component leakage current becomes zero, a condition corresponding to R-phase where 90° phase-shifted component leakage current of R-phase is plus + is Irs′=39 with which the active component leakage current of R-phase becomes zero. At this point, the 90° phase-shifted reactive component leakage current of R-phase is +40. Accordingly, it is understood that actual reactive component leakage current of R-phase flowing between the power line 3 and the ground due to the electrostatic capacitance is larger than those of the other phases by +40 mA, and actual active component leakage current of S-phase flowing between the power line 3 and the ground due to the insulation resistors is larger than those of the other phases by +39 mA.

3) The step of calculating a 90° phase-shifted component zero value of each phase 140 and the step of calculating an in-phase component zero value of each phase 150 will be described.

A. The Step of Calculating a 90° Phase-Shifted Component Zero Value of Each Phase 140

A reactive leakage current value generated by electrostatic capacitance with which a reactive component leakage current value becomes zero is calculated for each of three phases. This value is calculated to understand that active component leakage current of which component flows at the secondary side of the zero-phase current converter 10 if the reactive component leakage current Ic generated by the electrostatic capacitance becomes zero. Describing it easily, it is to make reactive component leakage currents generated by the electrostatic capacitances be balanced in all three phases. A reactive component leakage current value of R-phase is calculated first to find out the phase and magnitude of reactive component zero leakage current Ic′ that should be additionally flown through the primary winding of the zero-phase current transformer 10 to make Io1cr zero, i.e., the value of Equation 20 becomes zero. Io1rr and Io1cr of R-phase, Io1ᵣₛ and Io1cs of S-phase, and Io1rt and Io1_{ct} of T-phase described in the above example and stored in the memory unit 86 are read. Then, Icr′, Ics′, and Ict′ values are calculated so that the 90° phase-shifted reactive component leakage current of R-phase becomes zero, i.e., the value of Equation 16 becomes zero. If the Icr′, Ics′, and Ice values are put into Equation 15 and an in-phase component leakage current value Io1rr′ of R-phase is calculated, Io1rr′ becomes as shown in Equation 21. If the Icr′, Ics′, and Ict′ values are put into Equation 16 and a 90° phase-shifted component leakage current value Io1cr′ of R-phase is calculated, Io1cr′ becomes as shown in Equation 22.

$$\begin{matrix}If {Icr}^{′} is applied , & \\ Irr - \frac{Irs}{2} - \frac{Irt}{2} - \frac{\sqrt{3}}{2} Ics + \frac{\sqrt{3}}{2} Ict = - 19.5 \\ If {lcs}^{′} is applied , \\ Irr - \frac{Irs}{2} - \frac{Irt}{2} - \frac{\sqrt{3}}{2} ( Ics + {Ics}^{′} ) + \frac{\sqrt{3}}{2} Ict = - 19.5 - \frac{\sqrt{3}}{2} {Ics}^{′} \\ If {lcs}^{′} is applied , \\ Irr - \frac{Irs}{2} - \frac{Irt}{2} - \frac{\sqrt{3}}{2} Ics + \frac{\sqrt{3}}{2} ( Ict + {Ict}^{′} ) = - 19.5 + \frac{\sqrt{3}}{2} {Ict}^{′} & < Equation 21 > \\ If {lcr}^{′} is applied , & \\ ( Icr + {Icr}^{′} ) - \frac{Ics}{2} - \frac{Ict}{2} + \frac{\sqrt{3}}{2} Irs - \frac{\sqrt{3}}{2} Irt = 73.8 + {Icr}^{′} \\ If {lcs}^{′} is applied , \\ Icr - \frac{( Ics + {Ics}^{′} )}{2} - \frac{Ict}{2} + \frac{\sqrt{3}}{2} Irs - \frac{\sqrt{3}}{2} Irt = 73.8 - \frac{{Ics}^{′}}{2} \\ If {lct}^{′} is applied , \\ Icr - \frac{Ics}{2} - \frac{( Ict + {Ict}^{′} )}{2} + \frac{\sqrt{3}}{2} Irs - \frac{\sqrt{3}}{2} Irt = 73.8 - \frac{{Ict}^{′}}{2} & < Equation 22 >\end{matrix}$$

Since the value of Equation 22 becomes zero when Icr′=−73.8. Ics′=147.6, and Ict′=147.6, if the values are put into Equation 21 respectively, the zero-phase leakage currents become −19.5+j0, −147.3+j0, and 108.3+j0, and the Icr′, Ics′, and Ict′ values of R-phase are stored in the memory unit 86.

Next, if zero-phase leakage currents of S-phase and R-phase are respectively calculated in the same manner as that of R-phase, following results will be obtained.

The reactive component leakage current value of S-phase becomes zero when Icr′=−40.0, Ics′=20.0, and Ict′=−40.0, and if the values are put as described above, the zero-phase leakage currents become 39.9+j0, 73.6+j0, and 108.3+j0, and the Icr′, Ics′, and Ict′ values of S-phase are stored in the memory unit 86.

The reactive component leakage current value of T-phase becomes zero when Icr′=−107.5, Ics′=−107.5, and Ict′=53.8, and if the values are put as described above, the zero-phase leakage currents become 39.0+j0, −147.3+j0, and −54.1+j0, and the Icr′, Ics′, and Ict′ values of T-phase are stored in the memory unit 86.

B. The Step of Calculating an In-Phase Component Zero Value of Each Phase 150

The step of calculating an in-phase component zero value of each phase 150 of FIG. 25 is described. In a method almost similar to the step of calculating a 90° phase-shifted component zero value of each phase 140, an active component leakage current generated by insulation resistors, with which the active component leakage current value becomes zero, is calculated for each of three phases. This value is calculated to understand that how much reactive component leakage current flows at the secondary side of the zero-phase current converter 10 if the active component leakage current generated by the insulation resistors becomes zero. Describing it easily, it is to make active component leakage currents generated by the insulation resistors Ir be balanced in all three phases. An active component leakage current value of R-phase is calculated first to find out the phase of active component zero leakage current Ir′ that should be additionally flown through the primary winding of the zero-phase current transformer 10 to make Io1rr zero, i.e., the value of Equation 11 becomes zero. Io1rr and Io1rr of R-phase, Io1ᵣₛ and Io1cs of S-phase, and Io1rt and Io1_{ct} of T-phase described in the above example and stored in the memory unit 86 are read. Then, Irr′, Irs′, and Irt′ values are calculated so that the in-phase active component leakage current becomes zero, i.e., the value of Equation 15 becomes zero. If the Irr′, Irs′, and Irt′ values are put into Equation 16 and a 90° phase-shifted component leakage current value Io1cr′ of R-phase is calculated, Io1cr′ becomes as shown in Equation 23. If the Irr′, Irs′, and Irt′ values are put into Equation 15 and an in-phase component leakage current value Io1rr′ of R-phase is calculated, Io1rr′ becomes as shown in Equation 24.

$$\begin{matrix}If {Irr}^{′} is applied , & \\ Icr - \frac{Ics}{2} - \frac{Ict}{2} + \frac{\sqrt{3}}{2} Irs - \frac{\sqrt{3}}{2} Irt = 73.8 \\ If {lrs}^{′} is applied , \\ Icr - \frac{Ics}{2} - \frac{Ict}{2} + \frac{\sqrt{3}}{2} ( Irs + {Irs}^{′} ) - \frac{\sqrt{3}}{2} Irt = 73.8 + \frac{\sqrt{3} {Irs}^{′}}{2} \\ If {lrt}^{′} is applied , \\ Icr - \frac{Ics}{2} - \frac{Ict}{2} + \frac{\sqrt{3}}{2} Irs - \frac{\sqrt{3}}{2} ( Irt + {Irt}^{′} ) = 73.8 - \frac{\sqrt{3} {Irt}^{′}}{2} & < Equation 23 > \\ If {lrr}^{′} is applied , & \\ ( Irr - {Irr}^{′} ) - \frac{Irs}{2} - \frac{Irt}{2} - \frac{\sqrt{3}}{2} Ics + \frac{\sqrt{3}}{2} Ict = - 19.5 + {Irr}^{′} \\ If {lrs}^{′} is applied , \\ Irr - \frac{( Irs + {Irs}^{′} )}{2} - \frac{Irt}{2} - \frac{\sqrt{3}}{2} Ics + \frac{\sqrt{3}}{2} Ict = - 19.5 + \frac{{Irs}^{′}}{2} \\ If {lrt}^{′} is applied , \\ Irr - \frac{Irs}{2} - \frac{( Irt + {Irt}^{′} )}{2} - \frac{\sqrt{3}}{2} Ics + \frac{\sqrt{3}}{2} Ict = - 19.5 + \frac{{Irt}^{′}}{2} & < Equation 24 >\end{matrix}$$

Since the value of Equation 24 becomes zero when Irr′=19.5, Irs′=−39, and Irt′=−39, if the values are put into Equation 23 respectively, the zero-phase leakage currents become 0+j73.8, 0+j40, and 0+j107.6, and the Irr′, Irs′, and Irt′ values of R-phase are stored in the memory unit 86.

Next, if zero-phase leakage currents of S-phase and R-phase are respectively calculated in the same manner as that of R-phase, following results will be obtained.

The active component leakage current value of S-phase becomes zero when Irr′=147.3, Irs′=−73.7, and Irt′=147.3, and if the values are put as described above, the zero-phase leakage currents become 0−j147.5, 0−j20, and 0+j107.5, and the Irr′, Irs′, and Irt′ values of S-phase are stored in the memory unit 86.

The active component leakage current value of T-phase becomes zero when Irr′=−108.3, Irs′=−108.3, and Irt′=54.1, and if the values are put as described above, the zero-phase leakage currents become 0−j147.5, 0+j40.0, and 0−j53.8, and the Irr′, Irs′, and Irt′ values of T-phase are stored in the memory unit 86.

Next, the step of verifying the calculated data 160 is performed. Reactive component zero leakage current Ic′ values calculated and stored in the memory unit 86 in the step of calculating a 90° phase-shifted component zero value of each phase 140, with which the reactive component leakage current of each phase becomes zero, are combined by each case with Ir′ values calculated and stored in the memory unit 86 in the step of calculating an in-phase component zero value of each phase 150, with which the active component leakage current of each phase becomes zero, and a combination where an Io value corresponding to the zero-phase leakage current becomes zero is searched. The Ic′ values and the Ir′ values are combined case by case, and the recalculated Io value becomes zero. In this case, since the leakage current generated by the insulation resistor of S-phase is the largest, a selected combination is Irs′=−39.0 and Icr′=−40.0. Analyzing the meaning of the result, the active component leakage current generated by the insulation resistor of S-phase is larger than those of R-phase and T-phase by about 39 mA, and the reactive component leakage current generated by the electrostatic capacitance of R-phase is larger than those of S-phase and T-phase by about 40 mA. That is, it is understood that the insulation resistance of S-phase is the lowest, which means poor insulation, and the electrostatic capacitance of R-phase to the ground is the highest.

The step of displaying and outputting a variety of data shown in FIGS. 23 to 25 170 is described.

This is a step of displaying the combinations recalculated in the step of verifying the calculated data 160 and a result of performing the step of detecting Io1, and Vf of each phase 120, in which the detected data, such as the active component leakage current Ior=39 mA, reactive component leakage current Ioc=40 mA, zero-phase leakage current Io=76.3 mA, information on a phase where insulation is the most poor (e.g., S-phase in the example described above), information on a phase where the reactive component leakage current generated by electrostatic capacitance is the highest (e.g., T-phase in the example described above), or the like, is displayed on the display unit 84. In addition, insulation resistance R for the active component leakage current Ior=39 mA or electrostatic capacitance C for the reactive component leakage current Ioc=40 mA of the zero-phase voltage between the power line 3 and the ground detected in the step of detecting Io1, and Vf of each phase 120 can also be displayed.

Here, the insulation resistance R can be expressed as shown in Equation 13, and the electrostatic capacitance C can be expressed as shown in Equation 14. In Equations 13 and 14, the voltage amplification coefficient is an amplification-related coefficient of the voltage detecting means 30, and it is assumed that the amplification-related co-efficient of the leakage current detecting means 40 including the zero-phase current transformer 10 is one.

In addition, using various types of communication methods (RS-232, RS-485, RS-422, code division multiple access (CDMA), or power line communication), the data described above can be outputted to outside through the communication unit 90.

In addition, a variety of data described above is compared with an alarm setting value that is previously stored in the memory unit 86, inputted through the input unit 82, or received through the communication unit 90. If the alarm setting value is larger than the active leakage current Ior or Ir, or smaller than the insulation resistance R, warning alarm can be displayed on the display unit 84 or outputted through the communication unit 90.

### Other Embodiments

Next, other embodiments shown in FIGS. 3 to 7 describe that the leakage detecting apparatus of the present invention can be embodied in a variety of forms, i.e., the leakage detecting apparatus can be embodied in a system where the secondary side connection of the transformer 1 is a Y-connection or a delta-connection, in a three-phase three-wire or three-phase four-wire system, in a non-grounding system, or in a system where the voltage component of the power line 3 is implemented by detecting phase voltage or line voltage.

The difference between the connection diagram of the second embodiment of the insulation detecting apparatus according to the present invention shown in FIG. 3 and the connection diagram of the first embodiment shown in FIG. 2 is that the zero-phase current transformer 10, such as ZCT for detecting zero-phase leakage current Io, is installed in the middle of the power line 3 to detect the insulation state of the power line 3 including the load 4 in the embodiment of FIG. 2, whereas the zero-phase current transformer 10 is installed in the middle of the ground line 5 of the transformer 1 in the embodiment of FIG. 3, and the other aspects of the two embodiments are the same.

Next, the connection diagram of the third embodiment of the insulation detecting apparatus according to the present invention shown in FIG. 4 is a connection diagram for describing that the connection diagram of the third embodiment is almost the same as that of the first embodiment shown in FIG. 2 and the insulation detecting apparatus can be embodied in a three-phase four-wire system where the neutral phase (N-phase) is used, and the operational flow and detecting method of the insulation detecting apparatus 20 is the same as those described above.

Next, the connection diagram of the fourth embodiment of the insulation detecting apparatus according to the present invention shown in FIG. 5 is a connection diagram for describing that the insulation detecting apparatus can be embodied in a power line 3 where the secondary side connection of the transformer 1 is a delta connection and a phase of the delta connection is grounded, and the operational flow and detecting method of the insulation detecting apparatus 20 is the same as those described above.

Next, the connection diagram of the fifth embodiment of the insulation detecting apparatus according to the present invention shown in FIG. 6 is a connection diagram for describing that the insulation detecting apparatus can be embodied in a non-grounding system where the secondary side connection of the transformer 1 is a delta connection that is not grounded, and the operational flow and detecting method of the insulation detecting apparatus 20 is the same as those described above.

Next, the connection diagram of the sixth embodiment of the insulation detecting apparatus according to the present invention is a connection diagram for describing that the insulation state of the power line 3 can be monitored by detecting line voltage, and the operational flow and detecting method of the insulation detecting apparatus 20 is the same as those described above.

The leakage current detecting means 40 used in the aforementioned embodiments of the present invention shown in FIGS. 9 and 11 is configured in the sequence of detecting a leakage current component through the zero-phase current transformer 10, converting the detected leakage current component to a voltage component in the current-to-voltage conversion unit 41, amplifying a value converted to a voltage component through the amplification unit 42, and filtering the amplified value through the current filter unit 43. However, another embodiment of the leakage current detecting means shown in FIG. 22 is configured in the sequence of detecting a leakage current component through the zero-phase current converter 10, converting the detected leakage current component to a voltage component in the current-to-voltage conversion unit 41, filtering a value converted to a voltage component in the current filter unit 43, and then amplifying the filtered value through the amplification unit 42.

Although the voltage detecting unit 31 of the power line 3 is configured inside of the insulation detecting apparatus 20 to detect a voltage component in the embodiments of the present invention, there can be other embodiments where a part having a function of the voltage detecting unit 31 is configured outside of the insulation detecting apparatus 20. Although the current-to-voltage conversion unit 41 is configured inside of the insulation detecting apparatus 20 to detect leakage current, if an electronic component element such as a resistor is directly connected to the secondary side of the zero-phase current converter 10, there can be other embodiments where a part having a function of the current-to-voltage conversion unit 41 is configured outside of the insulation detecting apparatus 20. There also can be other embodiments where the amplification unit 42 is configured to have a function of the current-to-voltage conversion unit 41.

Although resistance or capacitance of the resistors or capacitors used in the voltage detecting unit 31 is the same for all three phases in the embodiments of the present invention, there can be another embodiment where previously known different values can be applied to three phases respectively.

There can be another embodiment where phase angles and leakage current of each phase are measured using a power factor meter, leakage current meter, or wattmeter, which has the same functions as those of the embodiments of the present invention, together with capability of measuring phase angles and leakage current.

Although the present invention has been described with reference to several preferred embodiments, the description is illustrative of the invention and is not to be construed as limiting the invention. Various modifications and variations may occur to those skilled in the art, without departing from the scope of the invention as defined by the appended claims.

1. An insulation detecting apparatus for a power line for detecting an insulation state of the power line, comprising:
a voltage detecting means 30 for transforming a voltage component of each of three phases of the power line including a load into a voltage component of a certain magnitude and collectively extracting voltage of each of the three phases;
a zero-phase current transformer 10 for detecting zero-phase leakage current flowing between the power line and ground;
a leakage current detecting means 40 for converting a leakage current component detected by the zero-phase current transformer 10 into a voltage component and extracting a frequency component lower than a certain frequency or a frequency component of a commercial frequency band;
a phase comparing means 50 for detecting a phase difference between an output value of each of the three phases of the voltage detecting means 30 and an output value of the leakage current detecting means 40;
an analog-to-digital conversion unit 60 for converting an analog component of the output value of the leakage current detecting means 40 into a digital component;
an operation controller 70 for reading a variety of data from an output value of the phase comparing means 50 and an output value of the analog-to-digital conversion unit 60, and outputting, operating, and controlling a variety of the read data; and
an input-output unit 80 for inputting and displaying a variety of data.

2. An insulation detecting apparatus for a power line for detecting an insulation state of the power line, comprising:
a voltage detecting means 30 for transforming a voltage component of the power line including a load into a voltage component of a certain magnitude and sequentially extracting a voltage component of each of the three phases, one phase at a time;
a zero-phase current transformer 10 for detecting zero-phase leakage current flowing between the power line and ground;
a leakage current detecting means 40 for converting a leakage current component detected by the zero-phase current transformer 10 into a voltage component and extracting a frequency component lower than a certain frequency or a frequency component of a commercial frequency band;
a phase comparing means 50 for detecting a phase difference between an output value of each of the three phases of the voltage detecting means 30 and an output value of the leakage current detecting means 40;
an analog-to-digital conversion unit 60 for converting an analog component of the output value of the leakage current detecting means 40 into a digital component;
an operation controller 70 for reading, outputting, operating, and controlling a variety of data; and
an input-output unit 80 for inputting and displaying a variety of data.

3. The apparatus according to claim 1, wherein the voltage detecting means 30 comprises:
a voltage detecting unit 31 for detecting a voltage component of each of three phases of the power line 3 including a load and transforming the voltage component into a voltage component of a certain magnitude; and
a voltage filter unit 33 for extracting a frequency component lower than a certain frequency or a frequency component of a commercial frequency band from the voltage component transformed by the voltage detecting unit 31.

4. The apparatus according to claim 2, wherein the voltage detecting means 30 comprises:
a voltage detecting unit 31 for detecting a voltage component of each of three phases of the power line 3 including a load and transforming the voltage component into a voltage component of a certain magnitude;
a phase selection unit 32 for selecting a voltage component of only one phase of three phases from the voltage component transformed by the voltage detecting unit 31; and
a voltage filter unit 33 for extracting a frequency component lower than a certain frequency or a frequency component of a commercial frequency band from the voltage component of the phase selected by the phase selection unit 32.

5. The apparatus according to claim 1 or 2, wherein the phase comparing means 50 comprises:
a voltage component waveform shaping unit 51 for shaping a waveform of the voltage component outputted from the voltage detecting means 30;
a current component waveform shaping unit 52 for shaping a waveform of the leakage current component outputted from the leakage current detecting means 40; and
a phase difference detecting unit 53 for detecting a phase difference of an output of the current component waveform shaping unit 52 from an output of the voltage component waveform shaping unit 51.

6. The apparatus according to claim 1 or 2, wherein the voltage detecting unit 31 is configured with any one of a resistor, a condenser, and a transformer having the same impedance between each phase of the three-phase power line and the ground.

7. The apparatus according to claim 1 or 2, wherein the leakage current detecting means 40 comprises:
the zero-phase current transformer 10 for detecting leakage current between the power line and the ground;
a current-to-voltage conversion unit 41 for converting a leakage current component detected by the zero-phase current transformer 10 into a voltage component;
an amplification unit 42 for amplifying the leakage current component converted by the current-to-voltage conversion unit 41; and
a current filter unit 43 for extracting a frequency component lower than a certain frequency or a frequency component of a commercial frequency band from the leakage current component amplified by the amplification unit 42.

8. The apparatus according to claim 1 or 2, wherein the leakage current detecting means 40 comprises:
the zero-phase current transformer 10 for detecting leakage current between the power line and the ground;
a current-to-voltage conversion unit 41 for converting a leakage current component detected by the zero-phase current transformer 10 into a voltage component;
a current filter unit 43 for extracting a frequency component lower than a certain frequency or a frequency component of a commercial frequency band from the leakage current component converted by the current-to-voltage conversion unit 41; and
an amplification unit 42 for amplifying the leakage current component extracted by the current filter unit 43.

9. The insulation detecting apparatus according to claim 1 or 2, further comprising a communication unit for remotely monitoring the insulation detecting apparatus from outside.

10. An insulation detecting method for a power line, which can detect an insulation state of the power line even when electrostatic capacitance between the power line and ground is in an unbalanced state, as well as in a balanced state, comprising the steps of:
allowing a leakage current detecting means 40 to detect a leakage current component Io1 from a zero-phase leakage current component detected at a secondary side of a zero-phase current transformer, allowing a voltage detecting means to detect a voltage component Vf by extracting only a frequency component, and detecting a phase difference of the leakage current component tot from the voltage component Vf of each of three phases outputted from the voltage detecting means 30;
calculating an in-phase component and a 90° phase-shifted component of the leakage current component Io1 of each phase;
calculating a 90° phase-shifted component zero value of each phase;
verifying data on active component leakage current or reactive component leakage current of each phase calculated and stored in a memory unit in the step of calculating a 90° phase-shifted component zero value of each phase; and
externally displaying and/or outputting a combination of data recalculated in the step of verifying calculated data and the data used in the step of detecting Io1, Vf, and of each phase.

11. An insulation detecting method for a power line, which can detect an insulation state of the power line even when electrostatic capacitance between the power line and ground is in an unbalanced state, as well as in a balanced state, comprising the steps of:
allowing the leakage current detecting means 40 to detect a leakage current component Io1 from a zero-phase leakage current component detected at a secondary side of a zero-phase current transformer, allowing a voltage detecting means to detect a voltage component Vf by extracting only a frequency component, and detecting a phase difference of the leakage current component Io1 from the voltage component Vf of each of the three phases outputted from the voltage detecting means 30;
calculating an in-phase component and a 90° phase-shifted component of the leakage current component Io1 of each phase;
calculating an in-phase component zero value of each phase;
verifying data on active component leakage current or reactive component leakage current of each phase calculated and stored in a memory unit in the step of calculating an in-phase component zero value of each phase; and
externally displaying and/or outputting a combination of data recalculated in the step of verifying calculated data and the data used in the step of detecting Io1, Vf, and of each phase.

12. An insulation detecting method for a power line, which can detect an insulation state of the power line even when electrostatic capacitance between the power line and ground is in an unbalanced state, as well as in a balanced state, comprising the steps of:
allowing a leakage current detecting means 40 to detect a leakage current component Io1 from a zero-phase leakage current component detected at a secondary side of a zero-phase current transformer, allowing a voltage detecting means to detect a voltage component Vf by extracting only a frequency component, and detecting a phase difference of the leakage current component Io1 from the voltage component Vf of each of three phases outputted from the voltage detecting means 30;
calculating an in-phase component and a 90° phase-shifted component of the leakage current component Io1 of each phase;
calculating a 90° phase-shifted component zero value of each phase;
calculating an in-phase component zero value of each phase;
verifying data on active component leakage current or reactive component leakage current of each phase calculated and stored in the memory unit in the step of calculating an in-phase component zero value of each phase or in the step of calculating a 90° phase-shifted component zero value of each phase; and
externally displaying and/or outputting a combination of data recalculated in the step of verifying calculated data and the data used in the step of detecting Io1, Vf, and of each phase.

13. The method according to claim 10, wherein as a method of detecting an active component leakage current generated by insulation resistors or reactive component leakage current generated by electrostatic capacitance in the step of calculating a 90° phase-shifted component zero value of each phase, a reactive component zero leakage current is calculated, with which the reactive component leakage current generated by the electrostatic capacitance between the power line and the ground becomes zero in each of three phases.

14. The method according to claim 11, wherein as a method of detecting an active component leakage current generated by insulation resistors or reactive component leakage current generated by electrostatic capacitance in the step of calculating an in-phase component zero value of each phase, an active component zero leakage current is calculated, with which the active component leakage current generated by the insulation resistors between the power line and the ground becomes zero in each of three phases.

15. The method according to claim 12, wherein as a method of detecting an active component leakage current generated by insulation resistors or reactive component leakage current generated by electrostatic capacitance in the step of calculating an in-phase component zero value of each phase, an active component zero leakage current and a reactive component zero leakage current is calculated, with which the active component leakage current generated by the insulation resistors and the reactive component leakage current generated by the electrostatic capacitance between the power line and the ground become zero in each of three phases.
